(19) United States
(12) Patent Application Publication
(10) Pub. No.: US 2026/0123271 A1
(43) Pub. Date: Apr. 30, 2026

(54) PEROVSKITE LAYER, METHOD OF PREPARING THE SAME AND PHOTOELECTRIC DEVICE

(71) Applicant: THE HONG KONG POLYTECHNIC UNIVERSITY, Hong Kong (CN)

(72) Inventors: Gang LI, Hong Kong (CN); Kuan LIU, Hong Kong (CN); Qiong LIANG, Hong Kong (CN)

(21) Appl. No.: 19/277,520

(22) Filed: Jul. 23, 2025

Related U.S. Application Data
(60) Provisional application No. 63/674,561, filed on Jul. 23, 2024.

(51) Int. Cl. H10K 85/50; H10K 30/40; H10K 85/10

(52) U.S. Cl. CPC H10K 85/50; H10K 30/40; H10K 85/151

(57) ABSTRACT

A polymer-embedded perovskite layer comprising a crosslinked polymer matrix and a perovskite compound, wherein the crosslinked polymer matrix comprises a first repeating unit represented by —CH₂CH₂SO₂CH₂CH₂— and a second repeating unit represented by a polyol and the perovskite compound is represented by Formula 1:(A⁺)_{y}[(A′⁺)₁₋ₓ(A″⁺)ₓ]_{1-y}(M²⁺)(X⁻)₃, wherein x is a numerical value ranging from 0-0.99, and y is a numerical value ranging from 0.01-0.99; M²⁺ is Pb²⁺, Sn²⁺, or Ge²⁺; A⁺ is Cs⁺ or Rb⁺; A′⁺ is H(C═NH₂)NH₂⁺; A″⁺ is CH₃NH₃⁺, CH₃CH₂NH₃⁺, or Me(C═NH₂)NH₂⁺; and X⁻ is one or more of Cl⁻, Br⁻, or I⁻. The polymer-embedded perovskite layer can achieve enhanced regularity on perovskite crystallization and effectively passivated perovskite surface so as to enhance their performance in photovoltaic devices.

### CROSS-REFERENCE TO RELATED APPLICATIONS

The present application claims priority from U.S. Provisional Patent Application No. 63/674,561, filed on Jul. 23, 2024, which is hereby incorporated by reference in its entirety.

### TECHNICAL FIELD

The present disclosure relates to a perovskite layer, a method of preparing the same and a photoelectric device.

### BACKGROUND

Photovoltaic (PV) technology has shown great potential in offering a clean and sustainable solution to the issue of global energy scarcity. The interest in organic-inorganic hybrid perovskite materials has been growing rapidly due to their advantageous characteristics, such as high charge carrier mobility and lifetime, tuneable bandgaps, high absorption coefficient, and good solubility in common polar aprotic solvents. These materials have been widely used in various optoelectronic and electronic applications, including solar cells, light-emitting devices, lasers, and photodetectors. Among them, solar cells based on organic-inorganic halide perovskites (OIHPs) have emerged as a leading technology in the field of emerging photovoltaics.

However, the intrinsic stability of the perovskite layer and key interfaces remains the primary challenge in the commercialization of perovskite solar cells (PSCs). This challenge mainly arises from the fragile and ionic nature of halide perovskite materials, which make them highly sensitive and reactive toward the ambient environment. Solution deposition of perovskite thin films would spontaneously induce high concentrations of intrinsic defects (e.g., halide vacancies, under-coordinated lead cations) at perovskite surface and grain boundaries (GBs). Such defects are likely to be detrimental to the device performance (especially open-circuit voltage, V_{OC}) and would accelerate the perovskite degradation under ambient atmosphere, especially humidity. It's well recognized that delicate control of perovskite formation and crystallization kinetics (nucleation and crystal growth rate) as well as various passivation strategies are of great significance to mitigate the perovskite defects issue to a great extent.

The interfacial strain caused by lattice distortion of the microscopic perovskite crystal structure directly affects its optoelectronic properties and accelerates perovskite degradation as well. Strain engineering has been developed as a novel approach to further enhance the performance (e.g., V_{OC}) and operational stability of devices. So far, this field is still lack of reports reaching 95% of the S-Q limit in V_{OC}.

The soft and elastic nature of polymers is highly valuable in regulating residual strain during perovskite formation, and provides intrinsic moisture resistance. Whereas, due to strong coordinate interaction with perovskite precursors, polymer-based complexes are easy to precipitate from perovskite solutions when incorporated in large amounts for regulation. An alternative approach is to incorporate cross-linkable ligands into perovskite precursor solutions or through an antisolvent technique and trigger in-situ polymerization under the stimulus of thermal or ultraviolet during or after the solidification of perovskite films. So far, most related works synchronously fed monomers into perovskites and induced spontaneous but uncontrollable polymerization, which might cause uncertainty of perovskite precursor stoichiometry and colloidal size, thus disrupting the delicate perovskite crystallization process.

There is a lack of methods that implements delicate perovskite crystallization manipulation and provides all-around protection of perovskites. Additionally, there is still a need to improve power conversion efficiency (PCE) and open-circuit voltage (V_{OC}) and minimize the voltage loss in perovskite solar cells. The subject matter described herein addresses at least some of these unmet needs.

### SUMMARY

The present disclosure provides strategies for enhancing the regulation on perovskite crystallization so as to enhance their performance in photovoltaic devices.

In a first aspect, provided herein is a polymer-embedded perovskite layer comprising a crosslinked polymer matrix and a perovskite compound, wherein the crosslinked polymer matrix comprises a first repeating unit represented by —CH₂CH₂SO₂CH₂CH₂— and a second repeating unit represented by a polyol and the perovskite compound is represented by Formula 1:

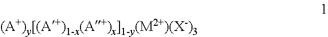

wherein x is a numerical value ranging from 0-0.99, and y is a numerical value ranging from 0.01-0.99; M²⁺ is Pb²⁺, Sn²⁺, or Ge²⁺;
A⁺ is Cs⁺ or Rb⁺;
A′⁺ is H(C═NH₂)NH₂⁺;
A″⁺ is CH₃NH₃⁺, CH₃CH₂NH₃⁺, or Me(C═NH₂)NH₂⁺; and
X⁻ is one or more of Cl⁻, Br⁻, or I⁻.

In certain embodiments, the polyol comprises a diolyl, a triolyl, a tetraolyl or a mixture thereof.

In certain embodiments, the polyol comprises ethylene glycolyl, propylene glycolyl, glyceryl, trimethylolpropanyl, trimethylolethanyl, erythritolyl, pentaerythritolyl, bis-trimethylolpropanyl, diethylene glycolyl, dipropylene glycolyl, ethoxylated pentaerythritolyl, sorbitolyl, or mixtures thereof.

In certain embodiments, M²⁺ is Pb²⁺; A⁺ is Cs⁺ and A″⁺ is CH₃NH₃⁺.

In certain embodiments, the perovskite comprises (Cs⁺)_{y}[(H(C═NH₂)NH₂⁺)₁₋ₓ (CH₃NH₃⁺)ₓ]_{1-y}(Pb²⁺)[I⁻)_{1-z}(Br⁻)_{z})]₃, wherein each of x, y and z is independently a numerical value ranging from 0.01-0.99.

In certain embodiments, the polyol is glyceryl.

In certain embodiments, each of x and y is independently a numerical value ranging from 0.01-0.1.

In certain embodiments, the crosslinked polymer matrix has a weight average molecular weight in the range of 20,000 to 140,000.

In certain embodiments, the molar ratio of the second repeating unit to the first repeating unit is 4-64:100.

In a second aspect, provided herein is a method for producing the polymer-embedded perovskite layer in the first aspect, the method comprising:
providing a perovskite precursor solution comprising one or more metal salts each independently represented by the formula MX₂, three or more salts each independently represented by the formulas AZ, A′Z or A″Z, divinyl sulfone, and a solvent, wherein M is Pb²⁺, Sn²⁺, or Ge²⁺, A is Cs⁺ or Rb⁺, A′ is H(C═NH₂)NH₂⁺, A″ is CH₃NH₃⁺, CH₃CH₂NH₃⁺, or Me(C═NH₂)NH₂⁺, X for each instance is independently Cl⁻, Br⁻, or I⁻, and Z for each instance is independently Cl⁻, Br⁻, or I⁻;
contacting the perovskite precursor solution with a polyhydric alcohol to form a crosslinking precursor solution; and
annealing the crosslinking precursor solution to form the perovskite layer.

In certain embodiments, the perovskite precursor solution comprises (Cs⁺)(I⁻), (H(C═NH₂)NH₂⁺)(I⁻), (CH₃NH₃⁺)(Br⁻), (CH₃NH₃⁺)(Cl⁻), (Pb²⁺)(Br⁻)₂, and (Pb²⁺)(I⁻)₂.

In certain embodiments, the solvent comprises dimethyl formamide, dimethyl sulfoxide, N-methyl-2-pyrrolidone (NMP), N,N′-dimethylpropyleneurea (DMPU), or mixtures thereof.

In certain embodiments, the volume ratio of divinyl sulfone to the solvent is 1-20:100.

In certain embodiments, the one or more metal salts have a concentration from 0.2 to 1.5 M in the perovskite precursor solution.

In certain embodiments, the molar ratio of polyhydric alcohol to divinyl sulfone is 4-64:100.

In certain embodiments, the crosslinking precursor solution is annealed at a temperature of 100-120° C.

In a third aspect, provided herein is a photoelectric device comprising the polymer-embedded perovskite layer in the first aspect.

In certain embodiments, the photoelectric device is a perovskite solar cell (PSC), a perovskite light-emitting diode, a perovskite laser, or a perovskite photodetector.

In certain embodiments, the open circuit voltage of the perovskite solar cell is 1.162-1.347V.

In certain embodiments, the photoelectric conversion efficiency of the perovskite solar cell is 17.78-25.98%.

### BRIEF DESCRIPTION OF THE DRAWINGS

The foregoing aspects and many of the attendant advantages of this invention will become more readily appreciated and understood by reference to the following detailed description, when taken in conjunction with the accompanying drawing.

FIG. 1 depicts asynchronous cross-linking illustration and divinyl sulfone characteristic. a, Schematic illustration of intermediate-dominated perovskite crystallization by pre-embedded DVS and all-around co-polymerization protection through the post-treatment of gly. b, Linear fitting of ²³Na NMR chemical shift and DN of the selected organic solvents to calculate the DN of DVS. c, ¹H NMR spectra of FAI, DVS, and FAI/DVS into DMSO-d6 solution, respectively. d, DFT calculation of adsorption energy of FA⁺ with different solvents.

FIG. 2 depicts crystallization dynamics in intermediate complex and perovskite formation. a, Ab initio MD simulations of perovskites precursors in DMF/DMSO and DMF/DVS solvent systems after ˜20 ps, in which iodoplumbate polyhedra are shown within 4 Å cutoff. b, Two-dimensional pseudo-colour absorption intensity mapping as a function of spin-coating time during the in-situ measurement. c, Pseudo-colour mapping of the UV-vis absorption spectra as a function of annealing time. d, In-situ XRD measurement of the control and DVS-gly based perovskite films during thermal annealing (intermediate phases presented by #and * symbol can be ascribed to FAI-DVS solvate). e, Corresponding XRD spectra as a function of annealing time. f, XRD intensity evolution of the perovskite main peak at 2θ=14.01°.

FIG. 3 depicts cross-linking and defects passivation. a, FITR spectra in selected region for the DVS solvent, as-cast DVS based perovskite film, and DVS-gly based perovskite final film after annealing. b, MALDI-TOF-MS measurement for the DVS/gly mixture solution. c-d, GI-XRD spectra in 2θ-sin 2ψ mode for c control and d DVS-gly based perovskite films at near surface region (50 nm depth), respectively. e, In-depth XPS spectra for the DVS-gly based perovskite film. f, TRPL decay for the control, DVS, and DVS-gly based perovskite films.

FIG. 4 depicts Device Performance. a, J-V curves of the best-performance control (TiO₂ ETL), control (TiO₂/SnO₂ QDs ETL), and DVS-gly-based devices. b, EQE spectrum of the DVS-gly based PSCs. c, V_{OC} distribution of the control (TiO₂ ETL), the control (TiO₂/SnO₂ QDs ETL), 7% DVS and DVS-gly based devices. d, Comparison of the V_{OC} with different bandgaps of PSCs from the literature to our work e EQE_{EL} as a function of the injection current density to calculate the nonradiative recombination loss. f, Energetic distribution of trap density for the control and DVS-gly based PSCs measured by admittance spectroscopy.

FIG. 5 depicts Perovskite Film Water Resistance and Device Stability. a, Image of a control perovskite film. b, Image of a DVS-gly-based perovskite film directly immersed in water. c-d, Long-term MPP tracking at elevated temperature (1-sun, 65±5° C., 50±5% RH encapsulated devices: FTO/TiO₂/SnO₂/PVSK/PTAA/Au) and room temperature (1-sun, 30±5° C., 60±5% RH, encapsulated devices: FTO/TiO₂/SnO₂/PVSK/spiro-OMeTAD/Au), respectively. e, thermal stability (dark, 85±5° C., N₂, unencapsulated device: FTO/TiO₂/SnO₂/PVSK/PTAA/Au).

FIG. 6 depicts ²³Na Nuclear Magnetic Resonance (NMR) Spectra for a series of common organic solvents and DVS.

FIG. 7 depicts photo images of PbI₂ power dissolved in DVS (left), FAI powder dissolved in DVS (middle), and DVS solvent (right).

FIG. 8 depicts XRD patterns of FAI powder and quasi-wet films deposited by FAI/DMSO and FAI/DVS solutions. Inset: the diffraction peaks of FAI-DVS solvate from 12° to 150.

FIG. 9 shows the relative dielectric constant of DVS calculated by the loop of DFT calculation and MD simulations.

FIG. 10 shows the implicit solvation model used in the DFT calculations to reflect the environment of solutions with er and nD values of corresponding solvents.

FIG. 11 depicts Pb-I Pair Distribution and Coordination. a, Radial distribution function and b, coordination number of Pb-I pairs in DMF/DMSO and DMF/DVS systems, respectively.

FIG. 12 depicts UV-vis absorption intensity evolution at the wavelength of 450 nm during anti-solvent assisted spin coating of the control and DVS-based perovskite inks.

FIG. 13 depicts in-situ UV-vis absorption intensity evolution at the wavelength of 450 nm for the control and DVS-gly based perovskite films during thermal annealing, and their corresponding crystal growth rate.

FIG. 14 depicts XRD Patterns Comparing Control and DVS-Based Perovskite Films and Annealing Time Variation. a, XRD patterns of the as-cast control and DVS-based perovskite films (intermediate phases presented by #and * symbol can be ascribed to FAI-DVS solvate); inset: intermediate phase presented by @ is assigned to MAI-PbI₂-DMSO based solvate. b, XRD patterns as a function of annealing time for the DVS-based sample in intervals of 4 minutes each (A is corresponding to the perovskite main peak).

FIG. 15 depicts full and enlarged FTIR Spectra. a, Full FITR spectra for the DVS solvent, as-cast DVS-based perovskite film, and DVS-gly based perovskite final film after annealing. b, Enlarged FTIR spectra in several regimes to provide a clear comparison of the characteristic signals between the as-cast DVS-based perovskite film and DVS-gly based perovskite final film.

FIG. 16 depicts nucleophile-mediated oxa-Michael addition reactions between DVS and gly.

FIG. 17 shows gel permeation chromatography (GPC) analysis for molecular weight distribution and cumulative percent curves under different molar ratio between gly versus DVS.

FIG. 18 shows XRD patterns and Full Width at Half Maximum (FWHM). a, XRD patterns of the final control, DVS-based, and DVS-gly-based perovskite films after thermal annealing. b, FWHM of the perovskite main peak at 2θ=14.01° for the corresponding samples.

FIG. 19 shows SEM top view images of the control, DVS-based, and DVS-gly-based perovskite films; scale bar: 1 m.

FIG. 20 shows grazing incident X-ray diffraction (GI-XRD) spectra: Near-Surface vs. Bulk. The GI-XRD spectra of DVS-gly based perovskite films at different tilt angles for the near-surface (50 nm depth, a) and bulk (200 nm depth, b) regions. The different curves correspond to tilt angles of 10°, 20°, 30°, 40°, and 50°, respectively, representing the variation of intensity with 20 at different sampling angles.

FIG. 21 shows steady-state PL spectra for the control and DVS-gly-based perovskite films.

FIG. 22 shows UPS results at the cut-off region for the control, DVS-based, and DVS-gly-based perovskite films.

FIG. 23 shows J-V curves with varying DVS ratios and hysteresis effect. a, J-V curves for the PSCs based on the ink with different volume ratios of DVS. b, Representative J-V curves of the DVS-gly-based devices under forward and reverse scanning, respectively.

FIG. 24 depicts the J-V curves at different gly concentrations (molar ratio versus DVS, from 0 to 64 mol %).

FIG. 25 shows certified PCE results from a Taiwan Accreditation Foundation (TAF) accredited photovoltaic certification laboratory (Enli Tech. Optoelectronic Calibration Lab., Taiwan). The certified PCE is 24.63%-certified aperture with an area of 0.067 cm².

FIG. 26 shows a Certificate of Accreditation for Enli Tech. Optoelectronic Calibration Lab., Taiwan.

FIG. 27 shows calculation of the bandgap for the DVS-gly based perovskite films through EQE spectra. E_{g}^{IP} can be determined by the maximum differential value of EQE.

FIG. 28 shows J-V Curves of Devices with Varying Perovskite Bandgaps. J-V characteristics of the control and DVS-gly based devices in p-i-n structure with different perovskite bandgaps (a, 1.53 eV; b, 1.65 eV; c, 1.77 eV; d, 1.85 eV).

FIG. 29 shows a J-V curve for the DVS-gly based minimodule (3-subcells, 3.6*3.6 cm2 substrate, active area:5.85 cm²).

FIG. 30 shows EQEEL and EL Spectra. a, EQEEL as a function of the applied voltage bias for the DVS-gly-based PSCs when operating as LEDs. b, EL spectra for the representative DVS-gly-based device under voltage bias from 1 to 1.5 V.

FIG. 31 depicts derived dark radiative recombination current and V_{OC} loss analysis. a, External quantum efficiency and derived dark radiative recombination current. b, V_{OC} loss analysis for control and DVS-gly-based perovskites.

FIG. 32 depicts Nyquist plots and impedance analysis. a, Nyquist plots of the control and DVS-gly based PSC, Inset: equivalent circuit for the simulation of charge transfer and recombination process. b, Nyquist plots of the control in the dark under 0.7 to 1.0 V bias voltage. c, The relationship between bias voltage and R_{S} for the corresponding PSCs. d, The relationship between bias voltage and R_{rec} for the corresponding PSCs.

FIG. 33 depicts long-term thermal and shelf storage stability. a, Long-term thermal stability (dark, 85±5° C., N₂, unencapsulated device: FTO/TiO₂/SnO₂/PVSK/spiro-OMeTAD/Au). b, Shelf storage stability (dark, 25±5° C., 20±5% RH, unencapsulated device: FTO/TiO₂/SnO₂/PVSK/spiro-OMeTAD/Au).

FIG. 34 depicts Table 1 listing ²³Na NMR shift for a series of common organic solvents to calculate the DN for DVS.

FIG. 35 depicts Table 2 listing DFT calculation results for the adsorption energy between FA⁺ and different solvents.

FIG. 36 depicts Table 3 listing average molecular weight of the copolymers obtained with different molar ratio between gly versus DVS, determined by gel permeation chromatography.

FIG. 37 depicts Table 4 showing setting parameters (ω, ψ, φ) for instrument angles in GI-XRD according to previous works.

FIG. 38 depicts Table 5 showing fitting parameters of the bi-exponential decay function in TRPL spectra for the corresponding perovskite films.

FIG. 39 depicts Table 6 showing photovoltaic parameters of the DVS-based devices with different volume ratios of DVS into DMF host solvent.

FIG. 40 depicts Table 7 showing photovoltaic parameters under different molar ratio of gly versus DVS.

FIG. 41 depicts Table 8 showing summary of the state-of-the-art values of V_{OC} deficit and non-radiative recombination loss (ΔV_{OC}, nr) reported in previous works and achieved in this work.

FIG. 42 depicts Table 9 showing Photovoltaic parameters for p-i-n structured devices based on different perovskite compositions.

FIG. 43 depicts Table 10 showing summary of the parameters for V_{OC} loss analysis.

FIG. 44 depicts Table 11 showing photovoltaic parameters of unencapsulated devices immersed into water as a function of time.

FIG. 45 shows the MALDI-TOF-MS data of some of the fragments in the DVS-gly network in FIG. 3b.

### DETAILED DESCRIPTION

### Definitions

Throughout the present disclosure, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the present disclosure and claims, unless the context requires otherwise, the word “include” or variations such as “includes” or “including”, will be understood to imply the inclusion of a stated integer or group of integers, but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, +1%, or +0% variation from the nominal value unless otherwise indicated or inferred.

The terms “weight percent,” “wt-%,” “percent by weight,” “% by weight,” and variations thereof, as used herein, refer to the concentration of a substance as the weight of that substance divided by the total weight of the composition and multiplied by 100. It is understood that, as used here, “percent,” “%,” and the like are intended to be synonymous with “weight percent,” “wt-%,” etc.

The processes and compositions of the present disclosure may comprise, consist essentially of, or consist of the components and ingredients of the present disclosure as well as other ingredients described herein. As used herein, “consisting essentially of means that the methods and compositions may include additional steps, components or ingredients, but only if the additional steps, components or ingredients do not materially alter the basic and novel characteristics of the claimed processes and compositions.

The term “polyhydric alcohol” used herein refers to a linear or branched alcohol compound bearing two or more hydroxyl groups, for example, from 2 to 8, or from 3 to 5, or from 3 to 4 of hydroxyl groups, in each of the molecules. The number of hydroxyl groups in a polyhydric alcohol compound is a measure of the amount of potentially reactive hydroxyl groups available for reaction.

The term “polyol” used herein refers to a radical obtained by removing hydrogen atoms from the hydroxyl groups of a polyhydric alcohol compound. The polyol herein comprises a diolyl, a triolyl, a tetraolyl and the like. The polyol can be represented by the formula 2 as follows:

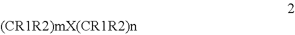

wherein each of m and n is a whole number selected from 1, 2, 3 and 4;
X is oxygen or a bond;
R1 for each instance is independently hydrogen or alkyl; and
R2 for each instance is independently an oxygen radical, a hydroxy, hydrogen or alkyl, wherein at least two R2 are an oxygen radical.

The term “diolyl” used herein refers to a diradical obtained by removing two hydrogen atoms from the hydroxyl groups of a diol compound. Similarly, “triolyl” refers to a triradical obtained by removing three hydrogen atoms from the hydroxyl groups of a triol compound, and so on.

The term of “perovskite solar cell(s)” used herein refers to solar cells that use a perovskite-structured material as the light-absorbing layer. When light is incident on the perovskite material, it excites electrons in the material, creating electron-hole pairs. The perovskite material has excellent charge-transport properties, allowing the electrons and holes to be separated and transported to the electrodes, where they can be collected as electrical current.

The perovskite solar cell in a normal structure typically consists of a transparent conductive oxide (TCO) layer, an electron transport layer (ETL), a perovskite light-absorbing layer, a hole transport layer (HTL), and a metal electrode. In a perovskite solar cell having an inverted structure, the order of the layers is reversed compared to the normal structure, with the TCO layer followed by the HTL, the perovskite layer, the ETL, and the metal electrode.

The present disclosure provides an insightful strategy to synergistically implement delicate perovskite crystallization manipulation and provide all-around protection at the perovskite surface and grain boundaries (GBs) during the perovskite forming process. The DVS units in the pre-embedded polymer dominates the FA-based intermediate transition during the delicate manipulation of perovskite crystallization and induced a three-dimensional co-polymerization through nucleophiles post-treatment upon as-cast films. It is validated that the polymer scaffold not only passivated the intrinsic defects at the perovskite surface and GBs but also released the residual strain at the near-surface region. Superior device performance is achieved with the lowest V_{OC} deficit among all perovskite systems. This strategy significantly improved the moisture resistance of perovskite films, and achieved much enhanced devices stability, which may advance the commercialization of this promising PV technology.

As a result, a maximum PCE of 25.22% (certified 24.6%) was achieved with a maximum V_{OC} of 1.229 V, corresponding to a mere 0.30 V deficit (for bandgap of ˜1.53 eV, coincident with the measured non-radiative recombination loss of only 52.5 mV from EQE_{EL}), reaching 97.5% of the theoretical S-Q V_{OC} limit, which is the higher than all the reported perovskite systems. The perovskite layer in the present disclosure can be universal across perovskite compositions and device architectures, delivering a promising PCE of 25.98% for certain p-i-n structured devices (Tables 9 in FIG. 42). All-around co-polymerization significantly enhanced the moisture resistance of perovskite films and devices and achieved superior operational stability at elevated temperature (ISOS-L-3: MPP, 65° C., 50% RH, T₉₈=1350 h) and room temperature (ISOS-L-1: MPP, 60% RH, T₉₀=1800 h), as well as thermal stability in dark (ISOS-D-2I: 85° C., N₂, T₉₅=1560 h).

The present disclosure provides a polymer-embedded perovskite layer comprising a crosslinked polymer matrix and a perovskite compound, wherein the crosslinked polymer matrix comprises a first repeating unit represented by —CH₂CH₂SO₂CH₂CH₂— and a second repeating unit represented by a polyol and the perovskite compound is represented by Formula 1:

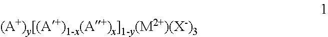

wherein x is a numerical value ranging from 0-0.99, and y is a numerical value ranging from 0.01-0.99;
M²⁺ is Pb²⁺, Sn²⁺, or Ge²⁺;
A⁺ is Cs⁺ or Rb⁺;
A′⁺ is H(C═NH₂)NH₂⁺;
A″⁺ is CH₃NH₃⁺, CH₃CH₂NH₃⁺, or Me(C═NH₂)NH₂⁺; and
X⁻ is one or more of Cl⁻, Br⁻, or I⁻.

In certain embodiments, M²⁺ is Pb²⁺; A⁺ is Cs⁺ and A″⁺ is CH₃NH₃⁺.

In certain embodiments, the perovskite comprises (Cs⁺)_{y}[(H(C═NH₂)NH₂⁺)₁₋ₓ(CH₃NH₃⁺)ₓ]_{1-y}(Pb²⁺)[I⁻)_{1-z}(Br⁻)_{z})]₃, wherein each of x, y and z is independently a numerical value ranging from 0.01-0.99.

In certain embodiments, perovskite compound comprises Cs_{0.03}(FA_{0.97}MA_{0.03})_{0.97}Pb(I_{0.97}Br_{0.03})₃, Cs_{0.05}(FA_{0.98}MA_{0.02})_{0.95}Pb(I_{0.98}Br_{0.02})₃, Cs_{0.35}FA_{0.65}PbI_{0.8}Br_{0.2}, Cs_{0.2}FA_{0.8}PbI_{0.7}Br_{0.3}, Cs_{0.2}FA_{0.8}PbI_{0.5}Br_{0.5}, or any mixture thereof.

In certain embodiments, x is a numerical value ranging from 0-0.50 or 0.01-0.1. In certain embodiments, x is 0.01, 0.05, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, or 0.99.

In certain embodiments, y is a numerical value ranging from 0.01-0.50 or 0.01-0.1. In certain embodiments, y is 0.01, 0.05, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, or 0.99.

In certain embodiments, z is a numerical value ranging from 0-0.99, 0-0.5 or 0.01-0.1. In certain embodiments, z is 0.01, 0.05, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, or 0.99.

In certain embodiments, the polyol comprises a diolyl, a triolyl, a tetraolyl, or a mixture thereof.

In certain embodiments, the polyol comprises ethylene glycolyl, propylene glycolyl, glyceryl, trimethylolpropanyl, trimethylolethanyl, erythritolyl, pentaerythritolyl, bis-trimethylolpropanyl, diethylene glycolyl, dipropylene glycolyl, ethoxylated pentaerythritolyl, sorbitolyl, or mixtures thereof.

In certain embodiments, the crosslinked polymer matrix has a weight average molecular weight in the range of 20,000 to 140,000. In certain embodiments, the crosslinked polymer matrix has a weight average molecular weight of 25,000, 30,000, 35,000, 40,000, 45,000, 50,000, 55,000, 60,000, 65,000, 70,000, 75,000, 80,000, 85,000, 90,000, 95,000, 100,000, 105,000, 110,000, 115,000, 120,000, 125,000, 130,000, 135,000, or 140,000, or any value or ranges therebetween.

In certain embodiments, the crosslinked polymer matrix has a number average molecular weight in the range of 10,000 to 125,000. In certain embodiments, the crosslinked polymer matrix has a number average molecular weight of 15,000, 20,000, 25,000, 30,000, 35,000, 40,000, 45,000, 50,000, 55,000, 60,000, 65,000, 70,000, 75,000, 80,000, 85,000, 90,000, 95,000, 100,000, 105,000, 110,000, 115,000, or 120,000, or any value or ranges therebetween.

In certain embodiments, the crosslinked polymer matrix has a polydispersity index of 1.10-1.80, for example, the polydispersity index is 1.15, 1.20, 1.25, 1.30, 1.35, 1.40, 1.45, 1.50, 1.55, 1.60, 1.65, 1.70, or 1.75, or any value or ranges therebetween.

In certain embodiments, the molar ratio of the second repeating unit to the first repeating unit is 4-64:100. In certain embodiments, the molar ratio of the second repeating unit to the first repeating unit is 5:100, 10:100, 15:100, 20:100, 25:100, 30:100, 35:100, 40:100, 45:100, 50:100, 55:100, or 60:100, or any value or ranges therebetween.

In certain embodiments, the perovskite grains have an average size in the range of 50-900 nm, 100-500 nm, or 300-500 nm. In certain embodiments, the perovskite compound grains have a size of 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, or any value or ranges therebetween.

The present disclosure further provides a method for producing the polymer-embedded perovskite layer, the method comprising:
providing a perovskite precursor solution comprising one or more metal salts each independently represented by the formula MX₂, three or more salts each independently represented by the formulas AZ, A′Z or A″Z, divinyl sulfone, and a solvent, wherein M is Pb²⁺, Sn²⁺, or Ge²⁺, A is Cs⁺ or Rb⁺, A′ is H(C═NH₂)NH₂⁺, A″ is CH₃NH₃⁺, CH₃CH₂NH₃⁺, or Me(C═NH₂)NH₂⁺, X for each instance is independently Cl⁻, Br⁻, or I⁻, and Z for each instance is independently Cl⁻, Br⁻, or I⁻;
contacting the perovskite precursor solution with a polyhydric alcohol to form a crosslinking precursor solution; and
annealing the crosslinking precursor solution thereby forming the perovskite layer.
The reaction products of the polydedric alcohol and divinyl sulfone (polyol) may include partially reacted products comprising unreacted alcohols, depending on the choice of the polyhedric alcohol, stoichiometry of the reagents and reaction conditions used.

In certain embodiments, the perovskite precursor solution comprises (Cs⁺)(I⁻), (H(C═NH₂)NH₂⁺)(I⁻), (CH₃NH₃⁺)(Cl⁻), (Pb²⁺)(Br⁻)₂, (Pb²⁺)(I⁻)₂, or mixtures thereof.

In certain embodiments, the solvent comprises dimethyl formamide (DMF), dimethyl sulfoxide, N-methyl-2-pyrrolidone (NMP), N,N′-dimethylpropyleneurea (DMPU), or mixtures thereof.

The selection and combination of these solvents can be optimized based on the specific perovskite composition and preparation process to achieve the best film quality and device performance. In certain embodiments, the solvent comprises or consists of dimethyl formamide (DMF).

In certain embodiments, the volume ratio of divinyl sulfone to the solvent (e.g. DMF) is 1-20:100. In certain embodiments, the volume ratio of divinyl sulfone to the solvent is 2:100, 3:100, 4:100, 5:100, 6:100, 7:100, 8:100, 9:100, 10:100, 11:100, 12:100, 13:100, 14:100, 15:100, 16:100, 17:100, 18:100, 19:100, or any value or ranges therebetween.

In certain embodiments, each of the one or more metal salts independently has a concentration from 0.2 to 1.5 M in the perovskite precursor solution. In certain embodiments, each of the one or more metal salts independently has a concentration of 0.2 M, 0.3 M, 0.4 M, 0.5 M, 0.6 M, 0.7 M, 0.8 M, 0.9 M, 1.0 M, 1.1 M, 1.2 M, 1.3 M, or 1.4M, or any value or ranges therebetween, in the perovskite precursor solution. In certain embodiments, the one or more metal salts have a concentration from 0.2625 to 1.47 M in the perovskite precursor solution.

In certain embodiments, each of AZ, A′Z or A″Z independently has a concentration in the range from 0.01 to 1.5 M in the perovskite precursor solution. In certain embodiments, each of AZ, A′Z or A″Z independently has a concentration of 0.02M, 0.04M, 0.06M, 0.08M, 0.1M, 0.2M, 0.3 M, 0.4 M, 0.5 M, 0.6 M, 0.7 M, 0.8 M, 0.9 M, 1.0 M, 1.1 M, 1.2 M, 1.3 M, or 1.4M, or any value or ranges therebetween, in the perovskite precursor solution. In certain embodiments, each of AZ, A′Z or A″Z independently has a concentration in the range from 0.04 to 1.41 M in the perovskite precursor solution.

In certain embodiments, the molar ratio of the polyhydric alcohol to divinyl sulfone is 4-64:100. In certain embodiments, the molar ratio of the polyhydric alcohol to divinyl sulfone is 5:100, 10:100, 15:100, 20:100, 25:100, 30:100, 35:100, 40:100, 45:100, 50:100, 55:100, or60:100, or any value ranges therebetween.

In certain embodiments, the method further comprises depositing the crosslinking precursor solution on a surface to form a wet film; and annealing the wet film to form the perovskite layer. In some embodiments, the crosslinking precursor solution may be deposited by the methods, such as spin coating, blade coating, spray coating, slot-die coating, inkjet printing and vapor deposition. In certain embodiments, the crosslinking precursor solution is deposited by spin coating.

Annealing the crosslinking precursor solution or the perovskite wet film may significantly impact the film's quality and the device's performance. Optimal annealing conditions can vary depending on the specific perovskite composition and the desired film properties. In certain embodiments, the crosslinking precursor solution or wet film is subjected to annealing at a temperature of 100-120° C., such as 100° C., 102° C., 104° C., 105° C., 106° C., 108° C., 110° C., 112° C., 114° C., 115° C., 116° C., 118° C., or 120° C., or any value or ranges therebetween.

In certain embodiments, the crosslinking precursor solution or the wet film is subjected to annealing for a time period of 5-80 min, or 10-60 min. In certain embodiments, the crosslinking precursor solution or wet film is subjected to annealing for a time period of 15 min, 20 min, 25 min, 30 min, 35 min, 40 min, 45 min, 50 min, or 55 min, or any value or ranges therebetween.

In certain embodiments, the method for producing the perovskite layer comprises: providing a perovskite precursor solution comprising (Cs⁺)(I⁻), (H(C═NH₂)NH₂⁺)(I⁻), (CH₃NH₃⁺)(Br⁻), (CH₃NH₃⁺)(Cl⁻), (Pb²⁺)(Br⁻)₂, (Pb²⁺)(I⁻)₂, divinyl sulfone, and DMF; contacting the perovskite precursor solution with glycerinum to form a crosslinking precursor solution; and
annealing the crosslinking precursor solution to form the perovskite layer.

Depending on processes and conditions for producing the perovskite layer, perovskite grains can form either monolayer or multilayer structures. For example, through slot-die coating processes and the regulation of specific precursor solutions, perovskite compound films with large-sized grains in a monolayer structure can be prepared. Monolayer structure is more suitable for reducing grain boundary defects and optimizing carrier transport pathways, especially in large-area fabrication. The formation of multilayer structure is closely related to crystallization kinetics, the stability of the precursor solution, and the solvent evaporation rate in the preparation process. For example, inconsistent crystallization rates between the upper and lower layers may lead to the stacking of grains in multiple layers. Multilayer structure can also enhance efficiency by optimizing the combination of different bandgap perovskite layers.

In certain embodiments, the perovskite grains form a single layer in the perovskite compound film. In certain embodiments, the perovskite grains form multi-layers in the perovskite compound film.

The present disclosure further provides a photoelectric device comprising the perovskite layer. The photoelectric device comprises perovskite solar cell (PSC), perovskite light-emitting diodes, perovskite lasers, and perovskite photodetectors.

In certain embodiments, the perovskite solar cell can have a normal structure, comprising a transparent or translucent conductive substrate, an electron transport layer, the perovskite compound film as described above, a hole transport layer and a metal electrode that are deposited sequentially. In certain embodiments, the perovskite solar cell can have a revert structure, comprising a transparent or translucent conductive substrate, a hole transport layer, the perovskite compound film as described above, an electron transport layer and a metal electrode that are deposited sequentially.

The transparent or translucent conductive substrate may be cleaned in advance by ultrasonication in solvents such as isopropanol, acetone and water. The substrate can also be treated with UV light for surface activation.

The transparent conductive oxide in the conductive substrate is selected from the group consisting of an indium tin oxide (ITO), a zinc oxide, a doped tin oxide, and a doped zinc oxide, such as a fluorine-doped tin oxide (FTO), or an aluminum-doped tin oxide (AZO), etc.

In certain embodiments, the transparent conductive oxide can include 90 wt % to 100 wt % of ITO, FTO, or AZO. In certain embodiments, the transparent conductive oxide can be composed primarily of ITO, FTO, or AZO. In certain embodiments, transparent conductive oxide is ITO.

In certain embodiments, a thickness of the perovskite compound film is 100 nm to 1000 nm, such as 100 nm, 200 nm, 300 nm, 400 nm, 500 nm, 600 nm, 700 nm, 800 nm, 900 nm, or 1000 nm.

Materials for forming the electron transport layer and the hole transport layer can be those commonly used in a perovskite solar cell. In certain embodiments, the electron transport layer may be formed by materials selected from titanium dioxide (TiO₂), tin oxide (SnO₂), zinc oxide (ZnO), zinc tin oxide (Zn₂SnO₄), [6,6]-phenyl-C₆₁-butyric acid methyl ester (PCBM), and perylene diimides (PDI). In certain embodiments, the hole transport layer may be formed by materials selected from 2,2′,7,7′-tetrakis(N,N-di-p-methoxyphenylamine)-9,9′-spirobifluorene (Spiro-OMeTAD), poly(triarylamine) (PTAA), poly(3,4-ethylenedioxythiophene) polystyrene sulfonate (PEDOT:PSS), poly(3-hexylthiophene-2,5-diyl) (P3HT), nickel oxide (NiOₓ), Copper(I) thiocyanate (CuSCN), 6,13-bis(triisopropylsilylethynyl)pentacene (TIPS-Pentacene), and copper phthalocyanine (CuPc).

In certain embodiments, the perovskite solar cell comprises an interfacial glue layer between the perovskite compound film and the charge transport layer (electron transport layer or hole transport layer). The interfacial glue may be selected from (3-iodopropyl)trimethoxysilane (Si(OCH₃)₃(CH₂)₃I), potassium tetrafluoroborate (KBF₄), trifluoromethane-sulfonamide (CF₃SO₂NH₂), aminopropyltriethoxysilane (H₂NCH₂CH₂CH₂Si(OC₂H₅)₃), polyhexamethylene guanidine hydrochloride, and 5,6-isopropyridine-L-ascorbic acid.

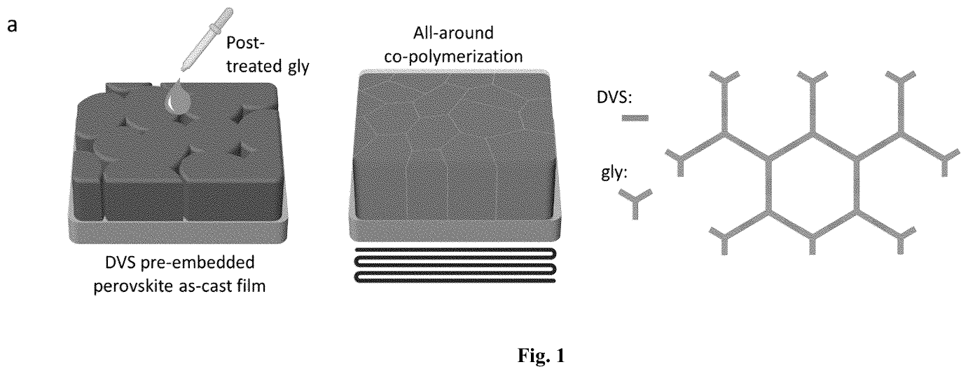

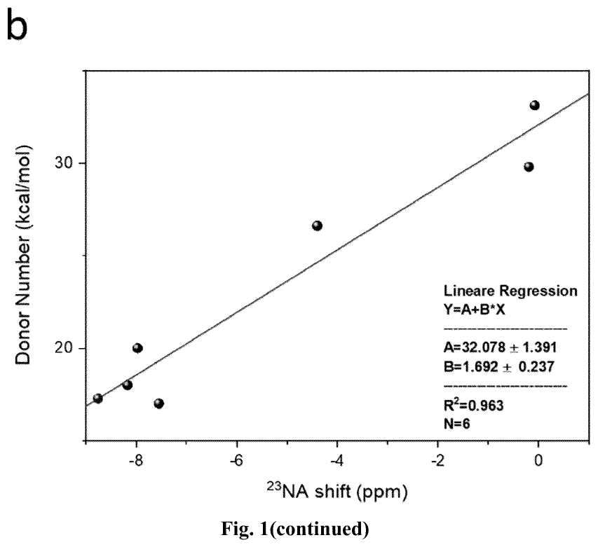

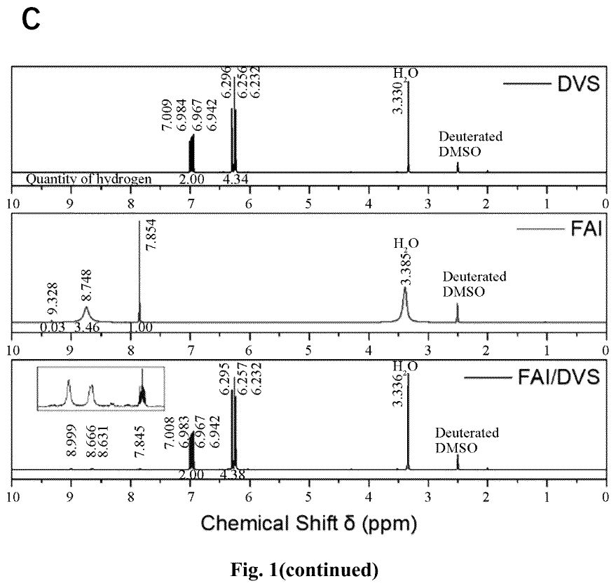

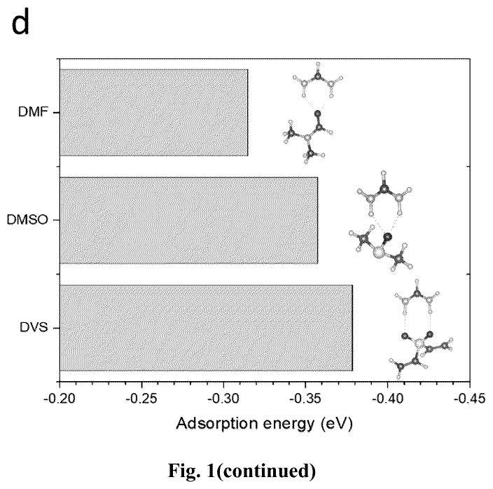

In the present disclosure, cross-linkable agents (e.g., DVS and Gly) were incorporated asynchronously to trigger a controllable co-polymerization at perovskite surface and GBs (FIG. 1a). In the following Examples, a new cross-linking initiator of DVS was firstly pre-embedded into perovskite precursor solutions. Also as a co-solvent with low coordination ability (low donor number, DN), DVS facilitated the intermediate-dominated perovskite crystallization manipulation through a favourable FAI-DVS-based solvate transition, while maintaining the kinetic balance between perovskite nucleation and crystal growth, and thus delivering high-quality perovskite films with low defect density. More importantly, the pre-embedded cross-linking initiator triggered three-dimensional co-polymerization into a controllable macro reticular structure, through a post-treated nucleophilic reagent, gly upon the as-cast perovskite films. The resulting co-polymer scaffold not only effectively passivated the intrinsic defects at the perovskite surface and GBs but also released the residual tensile strain at the near-surface region.

### EXAMPLES

### Raw Materials.

The following chemicals and solvents were used without further purification: lead iodide (PbI2) (Sigma-Aldrich, 99.99%), lead (II) bromide (PbBr₂) (Sigma-Aldrich, 99.999%), formamidinium iodide (FAI) (Greatcell Energy), methylammonium bromide (MABr) (Greatcell Energy), and methylammonium chloride (MACI). All of the solvents were bought from Sigma-Aldrich, including divinyl sulfone (containing 400-600 hydroquinone as inhibitor, >6%), dimethyl sulfoxide (DMSO), and N,N-dimethylformamide (DMF) (99.8%, anhydrous).

Fabrication of Devices with Perovskite Layers

### Example 1

This Example relates to fabrication of basic devices with pristine perovskite layers of Cs_{0.03}(FA_{0.97}MA_{0.03})_{0.97}Pb(I_{0.97}Br_{0.03})₃.

FTO/glass substrates with laser patterns (sheet resistance ≈12Ω per square) were cleaned in detergent, distilled water, acetone, and isopropanol, respectively. The FTO glass was submerged in a TiCl₄ solution at 70° C. for 60 minutes to produce the TiO₂ by employing the chemical bath deposition process. After that, the FTO substrate was repeatedly cleaned with distilled water and ethanol and dried for 30 minutes at 200° C. After 20 minutes of ultraviolet-ozone treatment, a thin coating of self-produced SnO₂ solution was spin-coated onto the previous TiO₂ layer for 30 seconds at 4000 rpm. Then, it was annealed for 60 mins at 200° C. in an ambient atmosphere.

The mixed powders of FAI (1.41 M), MABr (0.04 M), MACI (0.4 M), PbBr₂ (0.04 M), PbI₂ (1.47 M) in DMF/DMSO (4:1, v:v) were combined with 29 μL of CsI (1.5M, in DMSO) stock solution to create the Cs_{0.03}(FA_{0.97}MA_{0.03})_{0.97}Pb(I_{0.97}Br_{0.03})₃ perovskite precursor solution (bandgap=1.53 eV).

The precursor solution was stirred at room temperature overnight and then filtered before using. A 50 μL precursor solution was dripped onto the SnO₂ ETL surface prepared above. The spin-coating technique was utilized here to deposit perovskite thin films. Spin-coating is a method for creating thin films by dispensing a liquid solution onto a substrate that is then rotated at high speed, spreading the liquid and leaving behind a uniform layer as the solvent evaporates. Here we employed three spin-coating speed in three different stages: 1000 rpm for the first 5 s, to ensure the uniform cover of liquid solution onto the substrate, followed by 3000 rpm for the next 5 s, and finally 5000 rpm for the final 30 s, to reduce to thickness of the wet precursor film to the optimal condition. At the 10 s of the final step, 200 μL of toluene was dropped onto the substrate within is. The deposited layer was immediately annealed on a 120° C. hotplate for 60 min. Thermal annealing is a method to evaporate the residual solvent within in the as-cast perovskite film, and facilitate its crystallization. The first step is to set the hotplate to the desired temperature, and then put the deposited layer onto the hotplate, lasting the desired time.

The samples with the deposited layers were transferred into the glovebox and spin-coated with BABr (2 mg/mL, IPA) and spiro-OMeTAD (80 mg/mL in CB, 29 μL of tBP, and 17.5 μL of Li-TFSI mother solution), respectively, followed by a 10 mins annealing at 100° C. An 80 nm thick Au electrode was subsequently patterned by thermally evaporating on top of the device using a shadow mask.

### Example 2

This Example relates to fabrication of basic devices with pristine perovskite layers of Cs_{0.05}(FA_{0.98}MA_{0.02})_{0.95}Pb(I_{0.98}Br_{0.02})₃.

The fabricating procedure was similar as that described in Example 1 except that the perovskite precursor solution was prepared as follows. The mixed powders of FAI (1.40 M), MABr (0.04 M), MACI (0.4 M), PbBr₂ (0.04 M), PbI₂ (1.47 M) in DMF/DMSO (4:1, v:v) were combined with 50 μL of CsI (1.5M, in DMSO) stock solution to create the Cs_{0.05}(FA_{0.98}MA_{0.02})_{0.95}Pb(I_{0.98}Br_{0.02})₃ perovskite precursor solution (bandgap=1.53 eV).

### Examples 3-5

These Examples relate to fabrication of basic devices with other pristine perovskite layers.

The fabricating procedures were similar as that described in Example 1 except that the perovskite precursor solutions were prepared as follows, respectively.

The mixed powders of CsI (0.525 M), FAI (0.975 M), PbI₂ (1.05 M) and PbBr₂ (0.45 M) were dissolved in 1 mL of mixed DMF/DMSO solvent (vol/vol, 4:1) to create the Cs_{0.35}FA_{0.65}(PbI_{0.8}Br_{0.2})₃ perovskite precursor solution (bandgap=1.65 eV) (Example 3).

The mixed powders of CsI (0.24 M), FAI (0.96 M), PbI₂ (0.66 M) and PbBr₂ (0.54 M) were dissolved in 1 ml of mixed DMF/DMSO solvent (vol/vol, 4:1) to create the Cs_{0.2}FA_{0.8}(PbI_{0.7}Br_{0.3})₃ perovskite precursor solution (bandgap=1.77 eV) (Example 4).

The mixed powders of CsI (0.21 M), FAI (0.84 M), PbI₂ (0.2625 M) and PbBr₂ (0.7875 M) were dissolved in 1 ml of mixed DMF/DMSO solvent (vol/vol, 4:1), to create the Cs_{0.2}FA_{0.8}(PbI_{0.5}Br_{0.5})₃ perovskite precursor solution (bandgap=1.85 eV) (Example 5).

### Example 6

The Example relates to fabrication of target devices with divinyl sulfone (DVS)-based perovskite layers. The main fabricating procedures were similar as that described in Example 1 except that the perovskite precursor solutions were prepared as follows.

The mixed powders of FAI (1.41 M), MABr (0.04 M), MACI (0.4 M), PbBr₂(0.04 M), PbI2 (1.47 M) were added into DMF, and then combined with 29 of CsI (1.5M, in DMSO) stock solution to create the Cs_{0.03}(FA_{0.97}MA_{0.03})_{0.97}Pb(I_{0.97}Br_{0.03})₃ perovskite solution. Different amounts of DVS was incorporated into the perovskite solutions in DMF to form the perovskite precursor solutions, in which the volume ratios for DVS: DMF were 3:100, 7:100, 14:100, and 20:100, respectively.

Each of the as-cast perovskite film was posted-treated with glycerol (Gly) to form a crosslinked thin film. The molar ratio of Gly to DVS was 32:100. After the post-treatment, the as-cast perovskite films were transferred into a controlled ambient environment (20%-30% relative humidity, RH) and annealed onto a hotplate at 120° C. for 60 mins to facilitate the spontaneous cross-linking and perovskite crystallization.

### Example 7

The Example relates to fabrication of target devices with divinyl sulfone (DVS)-based perovskite layers. The main fabricating procedures were similar as that described in Example 6 except that the volume ratio for DVS: DMS was 7:100, and the molar ratios of Gly to DVS were 4.3:100, 21.3:100, 32:100, 42.7:100, and 64:100 for each sample.

### Example 8

The Example relates to fabrication of target devices with divinyl sulfone (DVS)-based perovskite layers. The main fabricating procedures were similar as that described in Example 6 except that the perovskite precursor solutions each comprise Cs_{0.05}(FA_{0.98}MA_{0.02})_{0.95}Pb(I_{0.98}Br_{0.02})₃, Cs_{0.35}FA_{0.65}PbI_{0.8}Br_{0.2}, Cs_{0.2}FA_{0.8}PbI_{0.7}Br_{0.3} or Cs_{0.2}FA_{0.8}PbI_{0.5}Br_{0.5} for each sample, in which the volume ratios for DVS: DMS was 7:100 and the molar ratio of Gly to DVS was 32:100.

### Characterization

### 1. Method

Crystalline structure was explored on a Rigaku Smart Lab X-ray diffractometer with Cu Kα radiation in a step of 0.01° and 0-20 scan mode from 5° to 50°. Perovskite film morphology was examined by a high-resolution field emission scanning electron microscopy (SEM) (TESCAN VEGA3). Grazing-incidence wide-angle X-ray scattering (GIWAXS) was investigated using a Xeuss 2.0 SAXS/WAXS laboratory beamline with a Cu X-ray source (8.05 keV, 1.54 Å) and a Pilatus3R 300K detector. The in-situ UV-vis absorption spectra was measured using an F20-UVX spectrometer (Filmetrics, Inc.) equipped with tungsten halogen and deuterium light sources. Appropriate amounts of FAI, DVS, and FAI/DVS were dissolved into DMSO-d6 to prepare the sample solutions. Their proton spectra were acquired using a 400 MHz NMR spectrometer. Steady-state photoluminescence (PL) and time-resolved decay spectra were measured using a PL spectrometer (Edinburgh Instruments, FLS920) with the excitation source of 636.2 nm picosecond pulsed diode laser (EPL-635, ˜5 nJ/cm2) and detected at 780 nm. TRPL decays spectra were fitted by the bi-exponential function:

$$I ( t ) = {A}_{1} exp ( - \frac{t}{{τ}_{1}} ) + {A}_{2} exp ( - \frac{t}{{τ}_{2}} ) .$$

Ultraviolet photoemission spectroscopy (UPS) measurement was carried out by a VG ESCLAB 220i-XL surface analysis system equipped with a monochromatic A1 K X-ray source (1486.6 eV) in a vacuum of 3.0×10⁻⁸ Torr. For the completed devices, J-V curves were obtained using a Keithley 2400 Source Meter under standard AM 1.5 G illumination (Enli Technology Co. Ltd., Taiwan), and the light intensity was calibrated by a standard KG-5 Si diode. Both forward (from −0.2 to 1.25 V) and reverse scanning (from 1.25 to −0.2 V) were performed with a delay time of 100 ms. The test areas (0.04 cm²) are typically defined by a metal mask with an aperture aligned with the active area. EQE spectra were measured with a QE-R 3011 EQE system (Enli Technology Co. Ltd., Taiwan) using 210 Hz chopped monochromatic light ranging from 300 to 850 nm. The EL EQE spectra was recorded by an LED photo-luminescence quantum yield measurement system (Enli Tech LQ-100) equipped with the Keithley 2400 Source Measure Unit. The non-radiative recombination loss (ΔV_{OC}, nr) can be derived from the EQE_{EL} at the injection current density equal to Jsc with the equation:

$$Δ {V}_{OC , nr} = - \frac{{k}_{B} T}{q} ln {EQE}_{E L} .$$

Thermal admittance spectroscopy (TAS) was performed to estimate the energetic distribution of trap density within perovskite films under an AC voltage with the frequency decreased from 10⁶ to 100 Hz according to the equations:

$${N}_{t} ( {E}_{ω} ) = - \frac{{V}_{bi}}{eW} \frac{dC}{d ω} \frac{ω}{{k}_{B} T} , {E}_{ω} = {k}_{B} T ln ( \frac{β {T}^{2}}{ω} ) ,$$

where V_{bi} is the built-in potential, W is the depletion width, C is the capacitance, ω is the applied angular frequency, and β is a temperature-independent parameter from the Arrhenius plot. V_{bi} and W could be calculated for a PSC device using the Mott-Schottky analysis.

### 2. Computational Details

All electronic structure calculations were performed using the ORCA (version 5.0.4) software package. ORCA is a versatile quantum chemistry program capable of performing various types of calculations, including density functional theory (DFT), Hartree-Fock (HF), and post-HF methods. All calculations were carried out using RI-B3LYP-D3(BJ) function with def2-TZVP basis set. To account for dispersion interactions, the DFT-D3 correlation correction was included in the calculations. This correction accounts for the long-range dispersion forces that are not adequately captured by standard DFT functionals. The D3 correction was applied with the Becke-Johnson damping scheme. In the calculations of adsorption energies, the counterpoise method was applied to reduce the basis set superposition error (BSSE), and the binding energies were calculated by the following equation:

$${E}_{coor} = {E}_{AB} + {E}_{BSSE} - {E}_{A} - {E}_{B} , \qquad ( 1 )$$

where E_{coor} is the BSSE correlated adsorption energy, E_{AB}, E_{A}, and E_{B} are the electrons energies of the total system, part A and part B, respectively. EBSSE is the correlation energy calculated by counterpoise method.

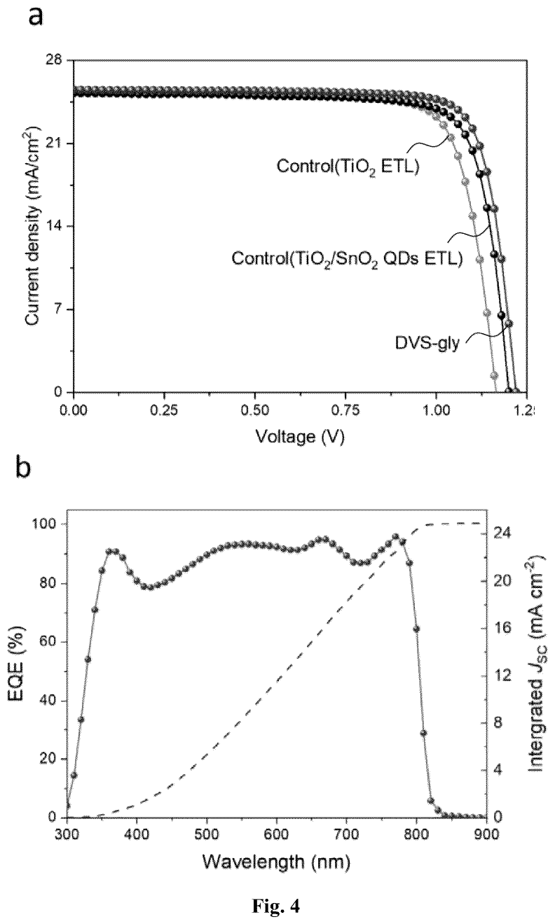

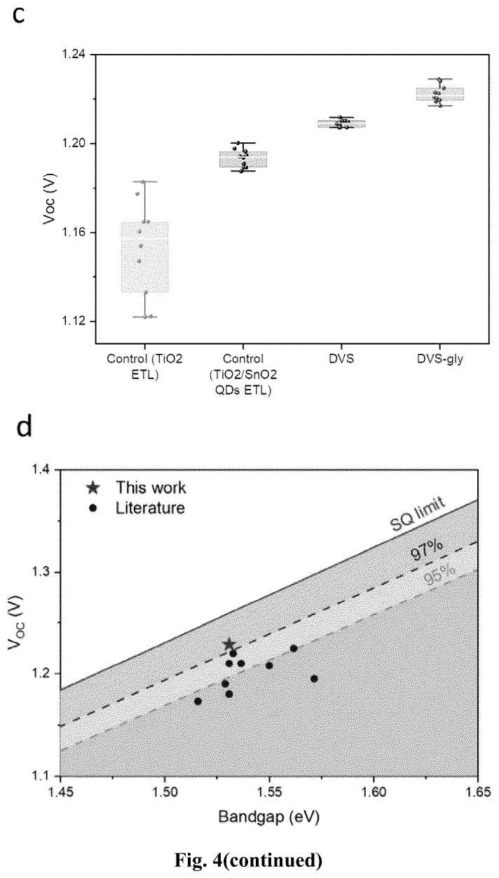

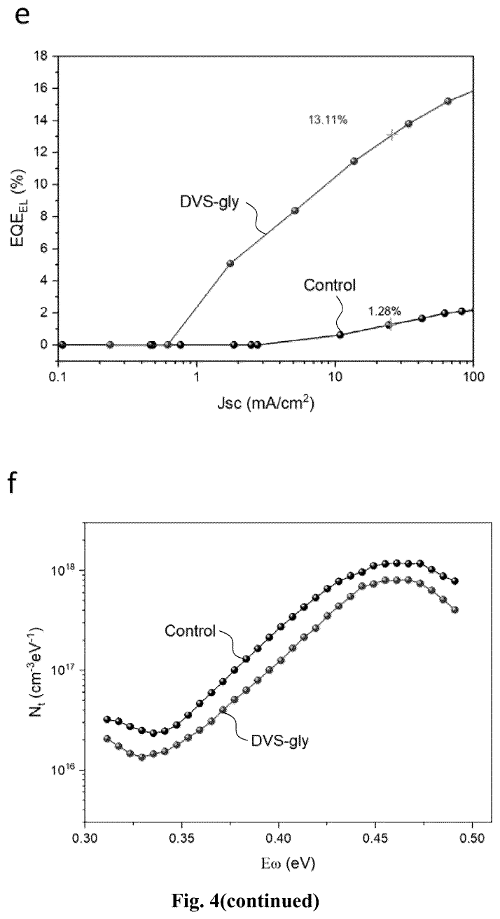

The implicit solvation model was used in the calculations to reflect the environment of solutions. The relative dielectric constant (εr) and refractive index (nD) of DMSO and DMF have already been defined in CPCM. The εr of DVS was calculated by the loop of DFT calculations and molecular dynamics (MD) simulations. Firstly, the geometry and electronic structure of DVS was calculated in the implicit solvation model with the er equals to 47 and nD equals to 1.48 (DFT step). Then the optimized structures and RESP2 charge were used to perform the MD calculations in GROMACS (version 2021.3). The atomic interactions were parameterized by the generation amber force field. Then the er in current state was obtained by the toolkits of GROMACS (MD step). The obtained er can be used in DFT step again to get the new structure and charges, and then the new structure and charges can be used in MD step to calculate the new εr. The loop of DFT step and MD step can be stopped until the εr outputted from two consecutive MD steps are equal. As shown in Supplementary FIG. 4, after 9 times looping, we get the calculated Cr of DVS (9.76).

To investigate the dynamic process of pre-nucleation stage in perovskite precursor solutions, we performed ˜20 ps Ab initio molecular dynamics (AIMD) simulations in CP2K package (version 7.1) in the framework of the density functional theory. The simulations were carried out in isothermal—isobaric ensemble (NPT), and Nose-Hoover thermostat and barostat were used to control the temperature and pressure of the simulated system. We performed two MD simulations of perovskite precursors in two different solution environments (DMF/DMSO and DMF/DVS, in which contains 7 Pb²⁺, 20 I⁻, 1 Cs⁺, 1 Br⁻, 6 FA⁺, 12 DMF and 12 DMSO or 12 DVS, respectively). Molecular orbitals of the valence electrons were expanded into DZVP-MOLOPT-SR-GTH basis sets, while atomic core electrons are described through Goedecker-Teter-Hutter (GTH) pseudopotentials. A plane-wave density cutoff of 560 Ry was adopted. The long range van der Waals interaction is described by the DFT-D3 approach. The radial distribution functions (RDF) of Pb-I pair was calculated in VMD software.

### Performance Test

### 1. Divinyl Sulfone Characteristics

The cross-linking initiator, DVS, was firstly incorporated into perovskite precursor solution and mixed with the solvent DMF in an appropriate volume ratio (0 to 20%, v:v). The conventional solvent system (DMF/DMSO=5:1, v:v) was used for comparison. It should be noted that the crystallization kinetics of perovskite film is not only determined by the boiling point, viscosity, and vapor pressure of solvent systems but also highly affected by the coordinate chemistry within the perovskite ink, as well as the intermediate phase transition.

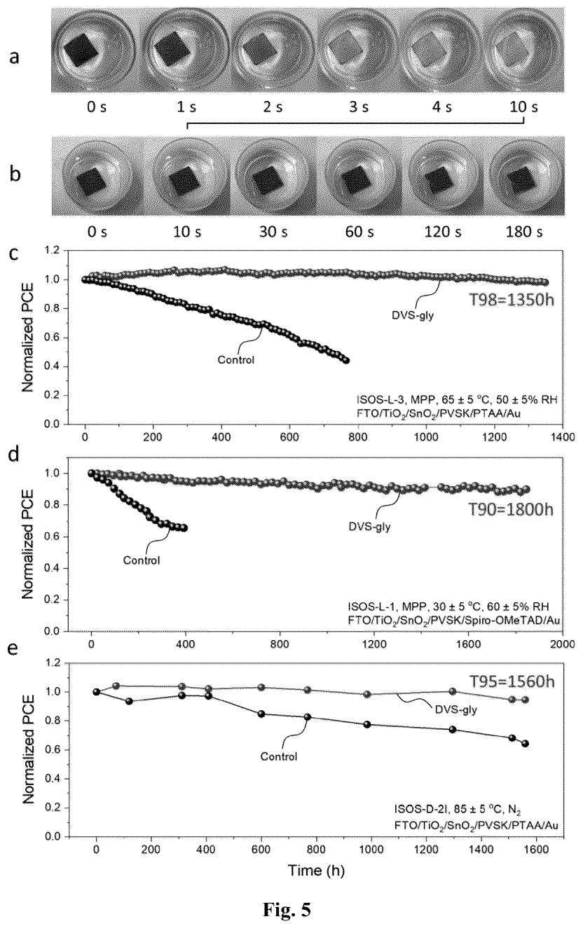

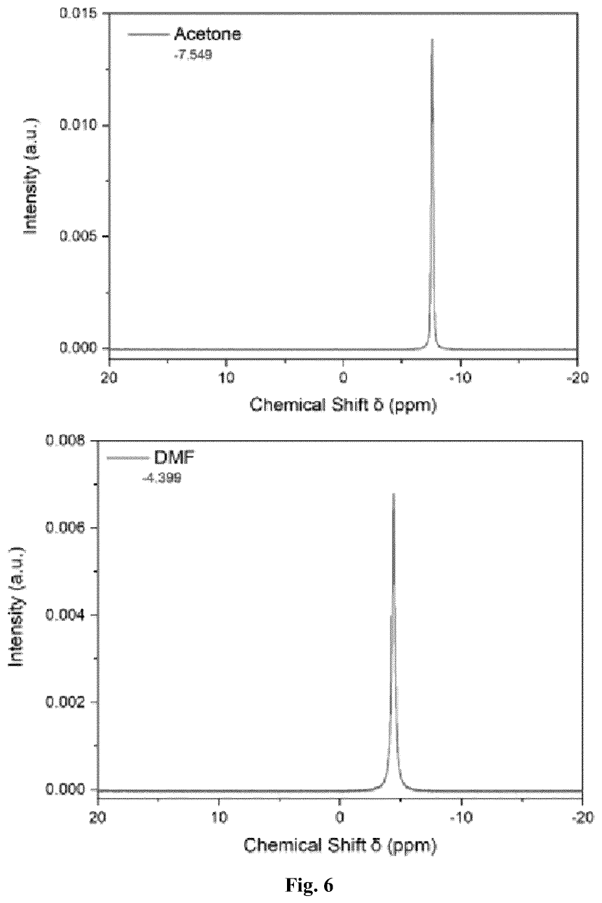

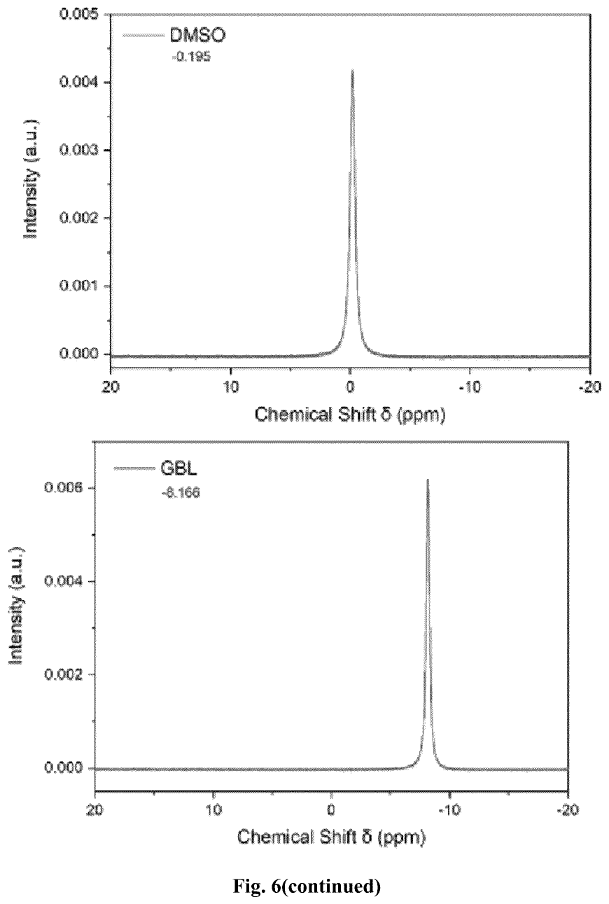

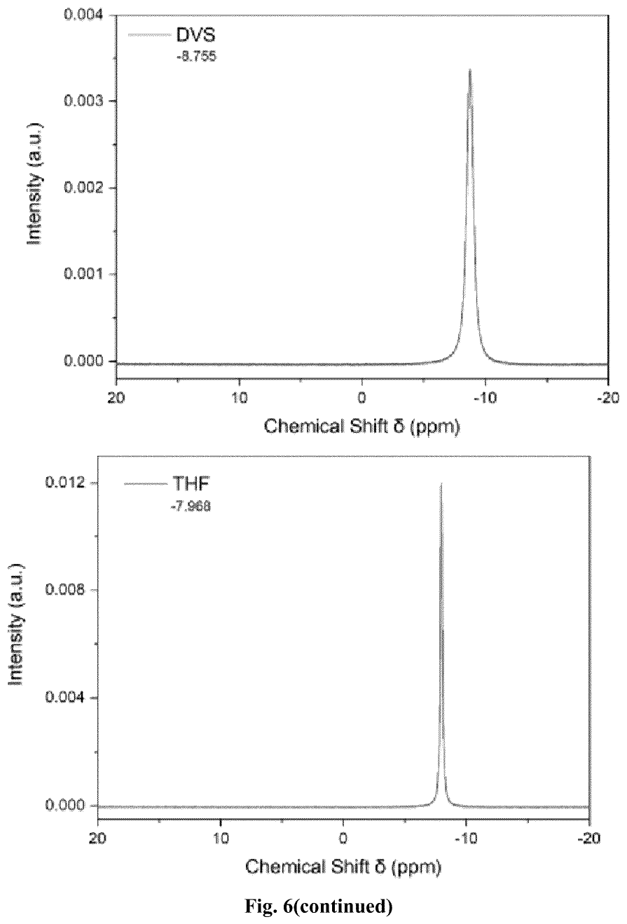

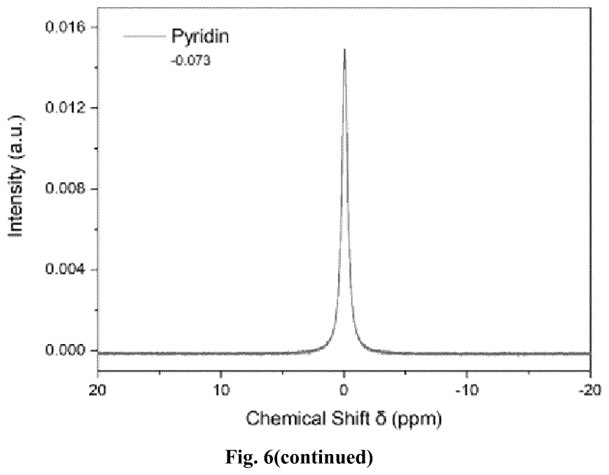

Donor number (DN) is a quantitative measurement of the Lewis basicity of a solvent that evaluates its coordinate interaction with Lewis acid (e.g., PbI₂). In order to study the precursor chemistry within the DVS-based solvent system, we first examined the DN of DVS by ²³Na nuclear magnetic resonance (NMR) spectroscopy. A series of common organic solvents were selected with reported DN values (Supplementary Table 1) to facilitate the study. An appropriate amount of NaClO₄ was dissolved into these solvents to prepare a 0.2 M solution. The DN of DVS was extracted from the linear fitting against ²³Na NMR shift to be 17.3 kcal/mol (FIG. 1b, FIG. 6, FIG. 34 (Table 1)), much lower than the commonly used aprotic organic solvents (e.g., DMSO).

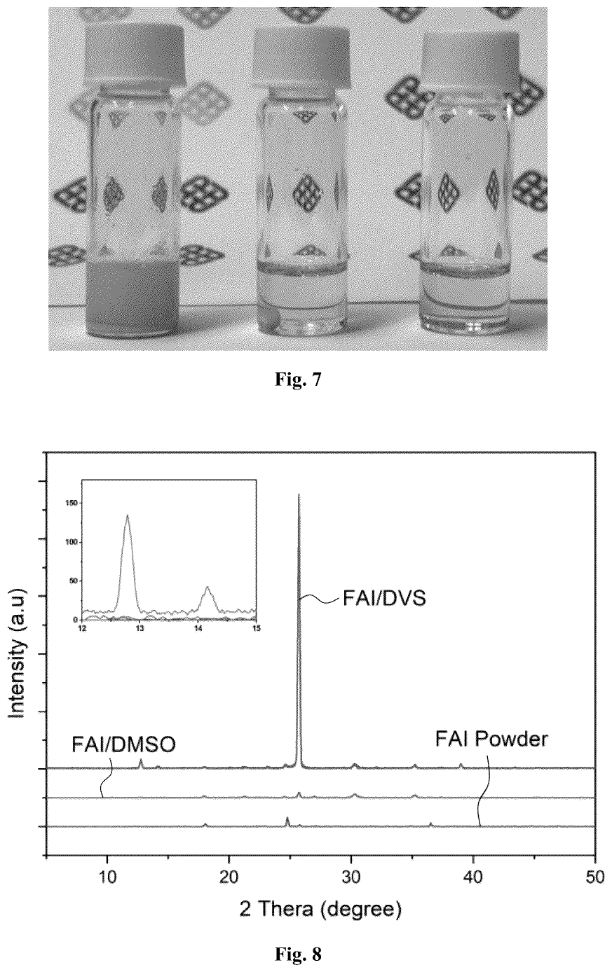

As a result, DVS is a low Lewis basic solvent, which exhibits weak coordinate interaction with PbI₂ (FIG. 7). In contrast, there is a strong interaction between DVS and ammonium iodide (e.g., FAI). We dissolved FAI into DVS delivering a clear solution but with a different colour compared with the DVS solvent (FIG. 7). When X-ray diffraction (XRD) spectroscopy was performed on the quasi-wet film using FAI in DVS solution, we observed new diffraction peaks at 2θ=12.78° and 14.19° besides the characteristic peaks of FAI powder (FIG. 8), which may indicate a new solvate phase based on FAI-DVS. ¹H NMR result also verifies this chemical interaction (FIG. 1c). The hydrogen chemical shifts are located at 7.854 and 8.748 ppm for pure FAI solution, whereas, in FAI/DVS solution, we observe a notable shift and split of the hydrogen signals at 7.845, 8.631 and 8.666 ppm, implying different chemical environment and a strong chemical interaction between DVS and FA⁺.

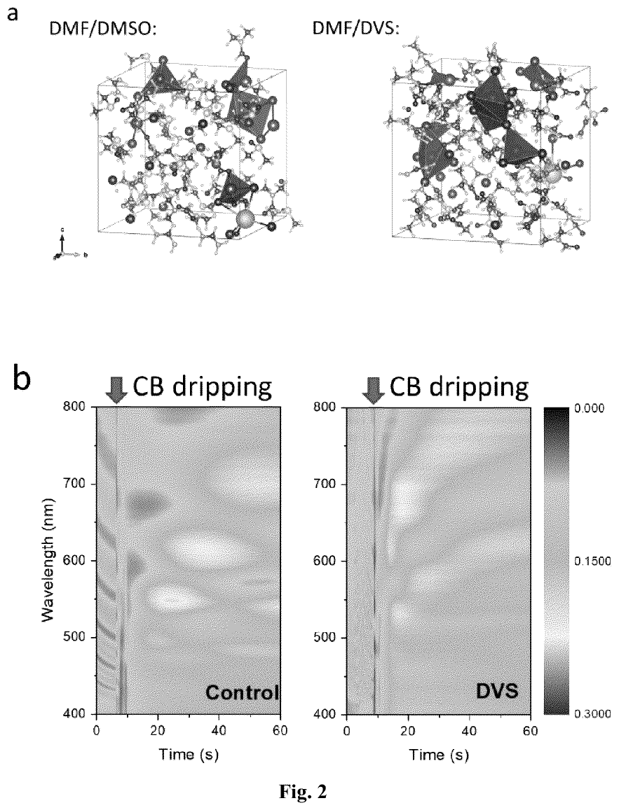

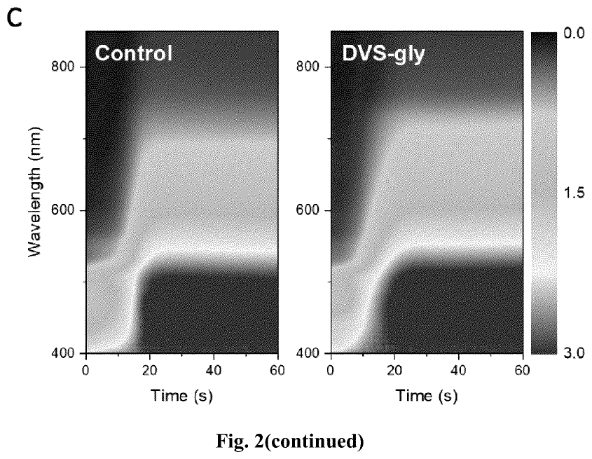

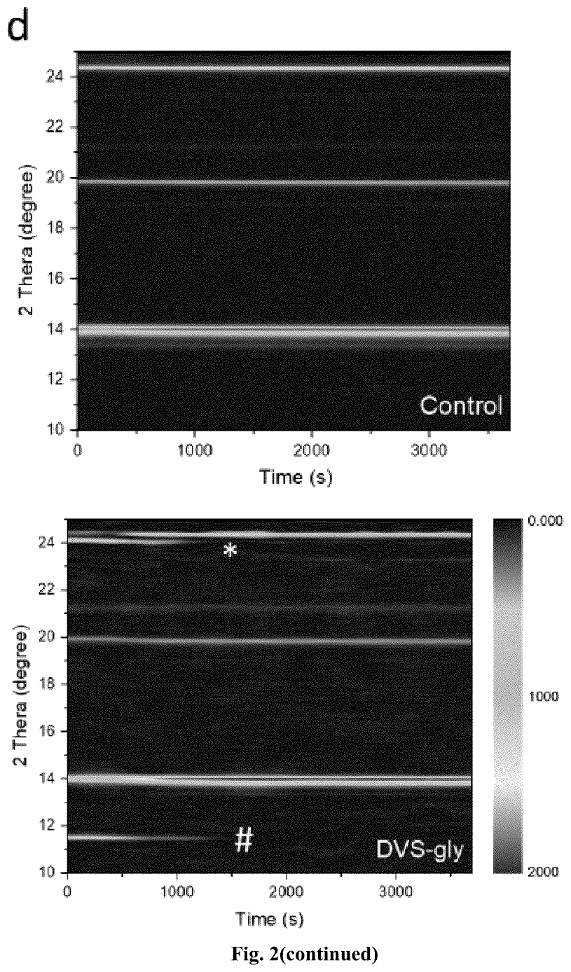

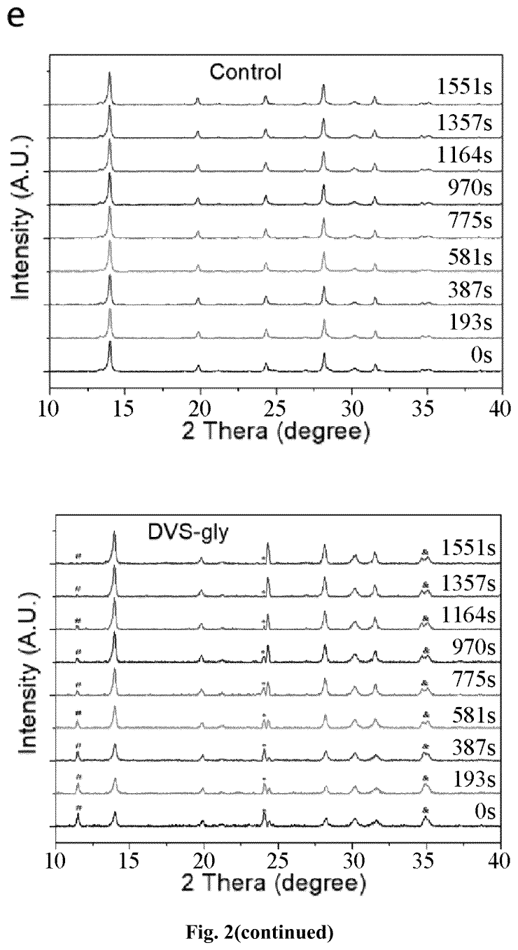

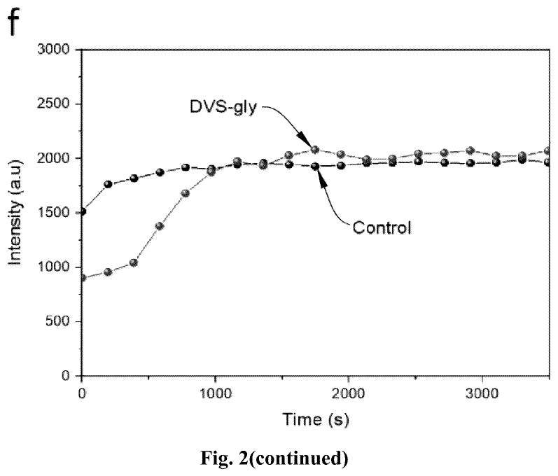

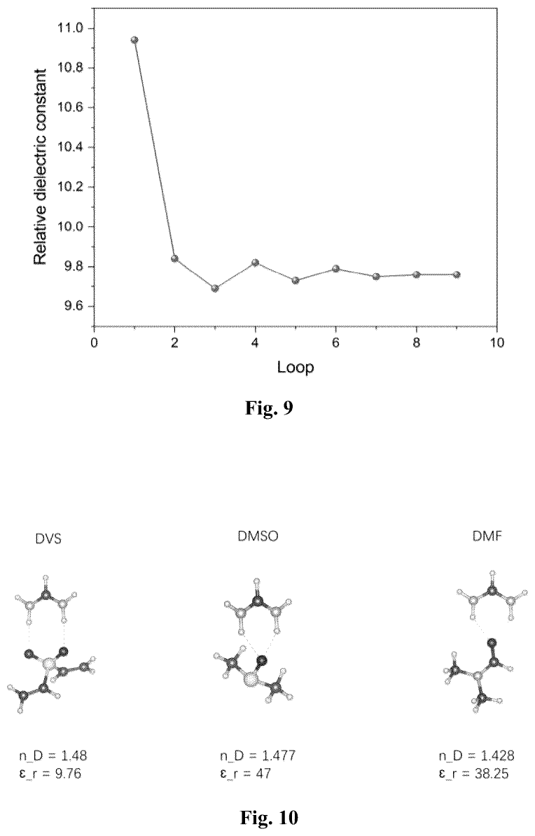

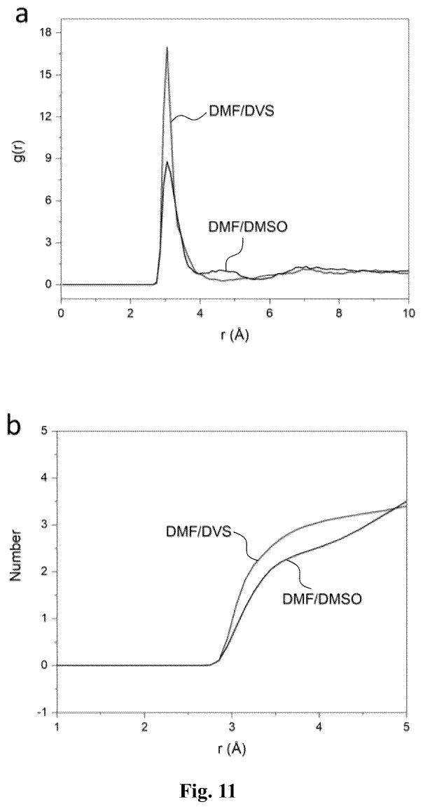

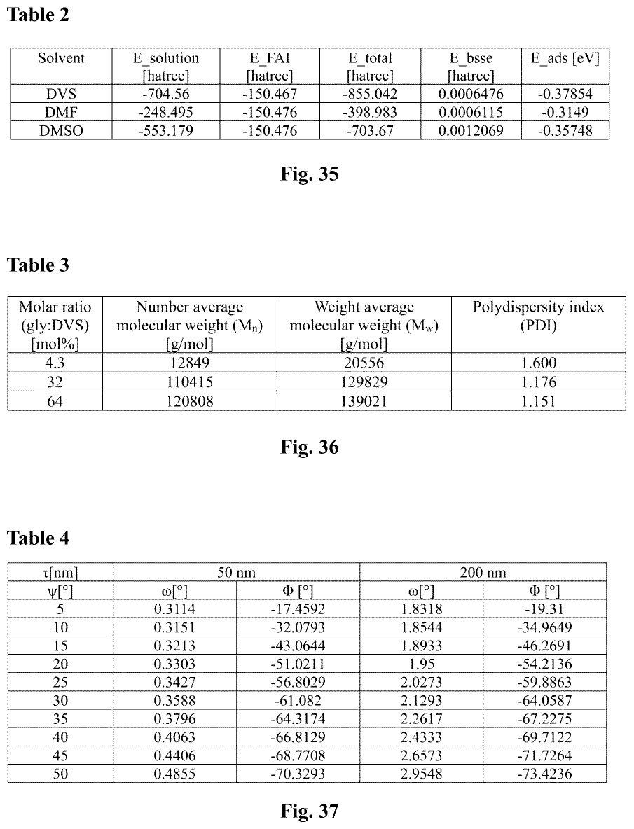

To further elucidate the solute-solvent interaction, we performed density function theory (DFT) calculation for the adsorption energy of FA⁺ with DMF, DMSO, and DVS, respectively (FIGS. 9-10, and Table 2 in FIG. 35, also see computation details in Supplementary Note 1). Compared with these current standard solvents, FA⁺ exhibited the largest adsorption energy with DVS, as shown in FIG. 1d, agreed well with our experimental results. The ab initio molecular dynamics (MD) was also conducted to understand the solvation effects at the pre-nucleation stage of perovskite precursor solutions. About 20 ps MD simulation was performed to evaluate the precursor-solvent mixtures evolution in two co-solvent systems (DMF/DMSO and DMF/DVS, see computation details in Supplementary Note 1). As shown in FIG. 2a, it is find that both Pb²⁺ and ammonium cations (FA⁺ and MA⁺) are highly coordinated with oxygen atoms in DMSO, thus forming individual small-size Pb-I clusters in DMF/DMSO system. However, in DMF/DVS system, it is find that more large-size Pb-I clusters of edge-sharing iodoplumbate start to form during the MD simulations (FIG. 2a and FIG. 11), which can be also expected due to the weak bonding between DVS and PbI₂ (low DN). These Pb-I clusters can act as nucleation centers to further facilitate nucleation of perovskite nanocrystals. One of the main insights from this MD simulation is that the solvent-solute interaction (for example, DMF-DVS) can be to tuned, with a direct impact on the subsequent perovskite nucleation and crystallization kinetics, as will be discussed below.

### 2. Crystallization Dynamics in Intermediate Complex and Perovskite Formation

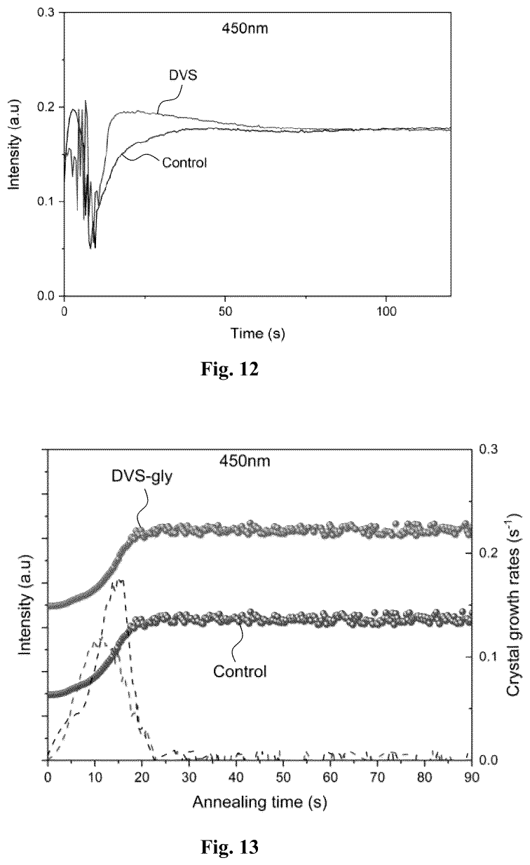

To provide a comprehensive insight into the perovskite crystallization kinetics affected by the DVS pre-embedded precursor solution, the time-resolved UV-vis absorption spectroscopy during the antisolvent-assisted spin-coating process was analysed. FIG. 2b shows the two-dimensional pseudo-colour absorption intensity mapping as a function of spin-coating time. Chlorobenzene (CB) was dripped upon the surface of perovskite wet film during spin coating (at 25 s) and the sample from DVS-based perovskite ink (DMF/DVS=5:1, v:v) shows much faster nucleation kinetics compared to that from DMSO-based ink (DMF: DMSO=5:1, v:v) (FIG. 12), coincident well with the result from MD simulation. The as-cast perovskite films were then treated with gly to trigger co-polymerization at the perovskite surface and GBs during thermal annealing. The same technique was used to measure the perovskite crystal growth rate in this process quantitively. FIG. 2c shows the pseudo-colour mapping of the in-situ UV-vis absorption spectra as a function of annealing time. The first derivative of absorbance at 450 nm versus time was performed and the average perovskite crystal growth rates were calculated to be 0.073 and 0.061 s⁻¹, respectively, for the control and DVS-gly based perovskite films (FIG. 13).

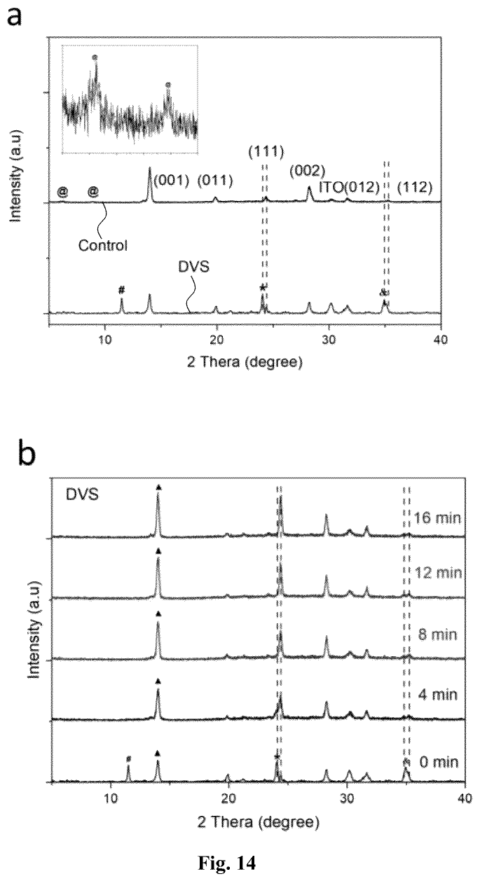

A detailed diagnosis of phase transitions that occurred during the thermal annealing process was performed by using in-situ XRD spectroscopy between the control and DVS-gly-based samples. For the as-cast control sample, besides the characteristic diffraction peaks of cubic FAPbI3 at 2θ=14.01°, 19.88°, 24.39°, and 28.24°, corresponding to (001), (011), (111) and (002) planes, we observed the signal related solvates at 2θ<10° (FIG. 14a). For comparison, the as-cast DVS-based perovskite film shows two distinct diffraction peaks at 2θ=11.51° and 24.05°, which gradually vanish along with thermal annealing (FIG. 2d, 2e, and FIG. 14b). This signal is likely ascribed to the FAI-DVS solvate, which confirms that cubic perovskite nanocrystals and additional FA-based intermediate complex transition co-exist in the DVS-based sample. The XRD intensity of the perovskite main peak at 2θ=14.01° was extracted as a function of annealing time, as shown in FIG. 2f. There is a pronounced delay of perovskite-crystal growth for the DVS-gly-based sample, which is mainly due to the necessary thermal energy to dissociate the intermediate and recrystallize into the cubic perovskite phase, as well as to induce the co-polymerization. It has been well recognized that delayed crystal growth is favoured to form high-quality perovskite films with better crystallinity, more dominated grain orientation, and lower defect density.

### 3. Cross-Linking and Defects Passivation

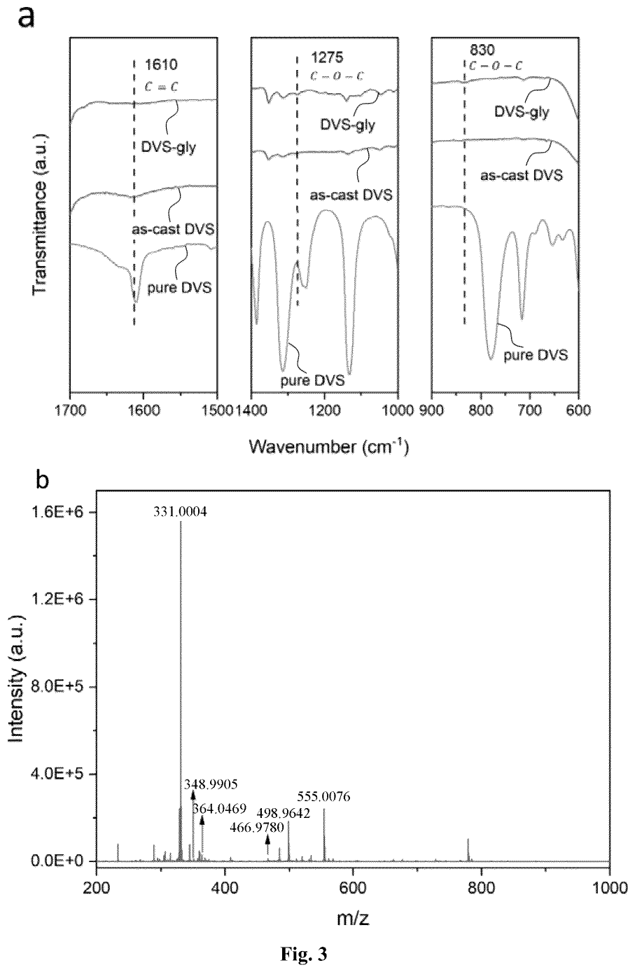

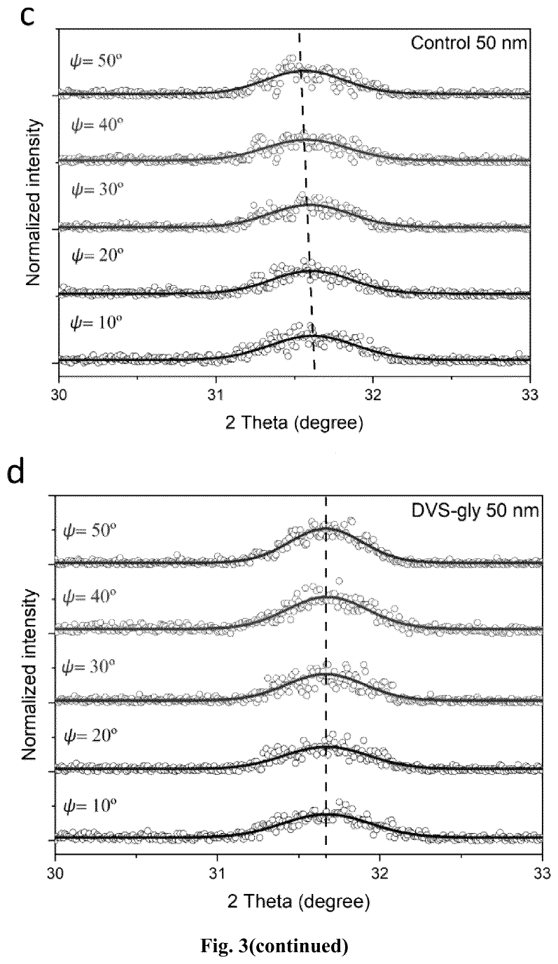

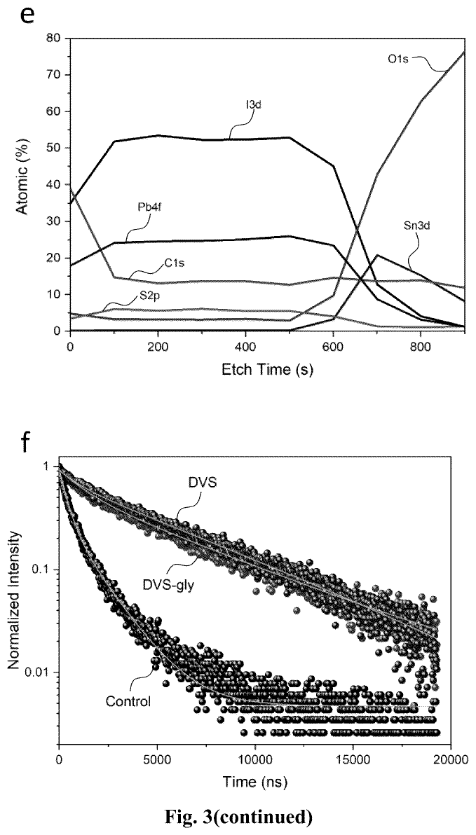

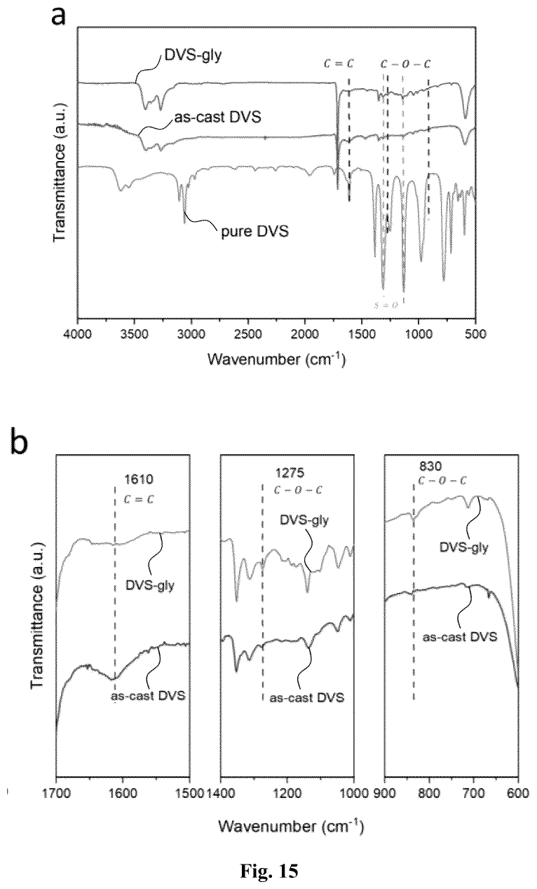

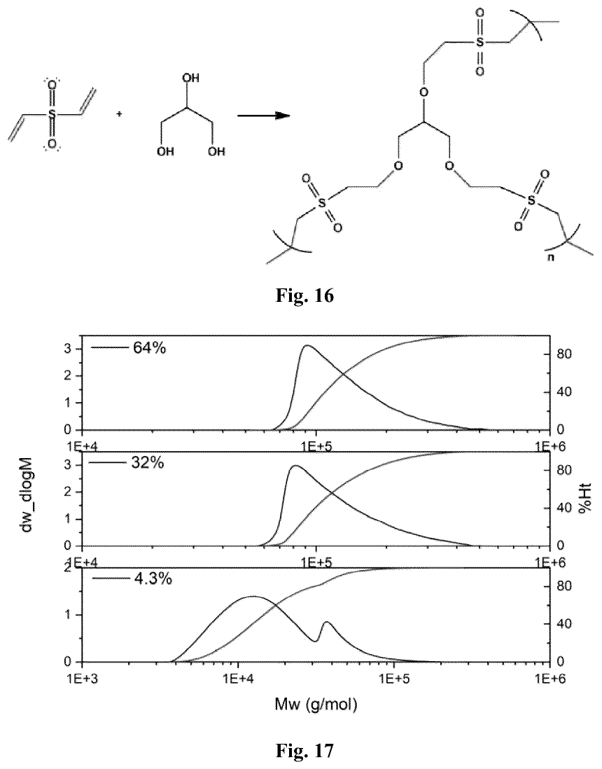

Cross-link reaction between the pre-embedded initiator (DVS) and post-treated nucleophilic reagent (gly) was confirmed through Fourier transform infrared spectroscopy (FTIR) and matrix-assisted laser desorption/ionization time-of-flight mass spectrometry (MALDI-TOF-MS). In FTIR, the characteristic signal of DVS with the C-C stretching vibration of vC=C at 1610 cm-1 was diminished after thermal annealing, while a distinct peak corresponding to the stretching vibration of C—O—C at 1275 cm⁻¹ and 830 cm⁻¹ appeared (FIG. 3a). This result validates the high reactivity in nucleophile-mediated oxa-Michael addition reactions between DVS and gly (FIG. 15). It should be noted that this addition reaction is the sole pathway for the controllable co-polymerization into the macro reticular structure. Furthermore, the characteristic peaks of S═O at 1310 and 1132 cm−1 are displayed in both the as-cast and post-treated samples, confirming the existence of DVS-gly co-polymer in final perovskite after thermal annealing (FIG. 16). MALDI-TOF-MS was further performed to examine the cross-link reaction, which verifies the presence of a few fragments in the DVS-gly network (FIG. 3b), and FIG. 45 shows the MALDI-TOF-MS data of some of the fragments in the DVS-gly network in FIG. 3b.

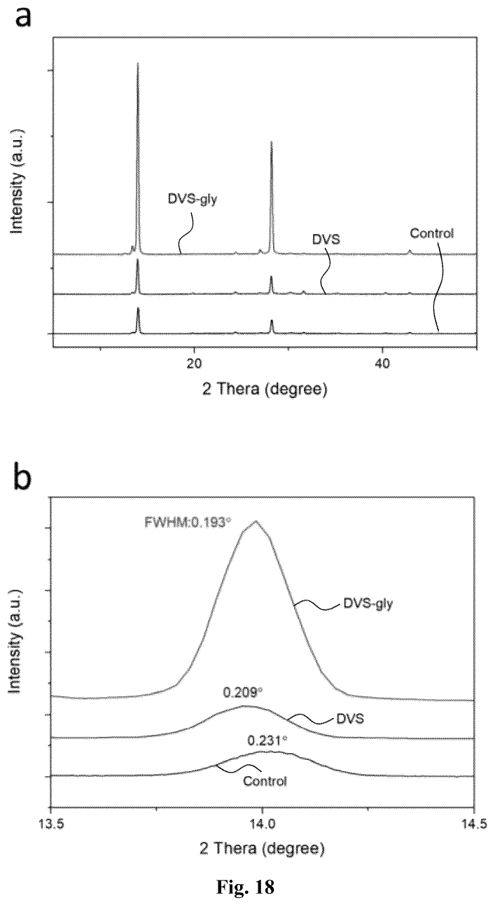

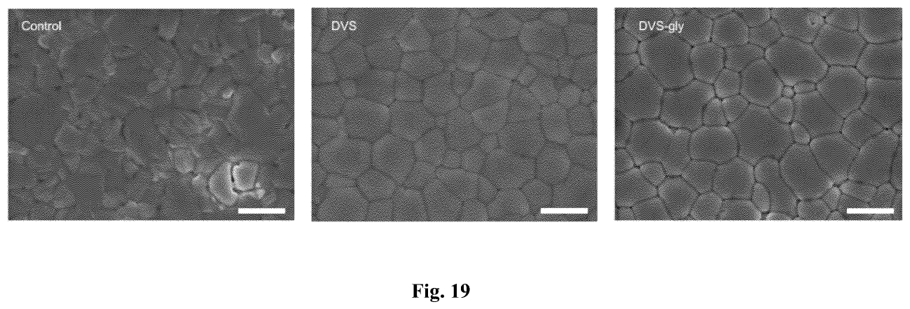

After the controllable co-polymerization and perovskite crystal growth, the control, DVS, and DVS-gly-based perovskite films showed identical XRD patterns, and no low-dimensional perovskites or non-perovskites were detected (FIG. 18a), corresponding to the characteristic diffraction peaks of cubic FAPbI₃, which may indicate that the DVS-gly co-polymer scaffold distributes at perovskite surface and GBs. Among them, the DVS-gly-based perovskite film exhibits the sharpest XRD patterns, with the full width at half maximum (FWHM) of (100) narrowed down from 0.2310 (control) to 0.193°, indicating better crystallinity (FIG. 18b). Top-view scanning electron microscopy (SEM) image of DVS-gly based perovskite film displays a homogenous and compact grain, with slightly enlarged GBs (FIG. 19), which validates that the DVS-gly scaffold was mainly constructed at perovskite GBs during thermal annealing.

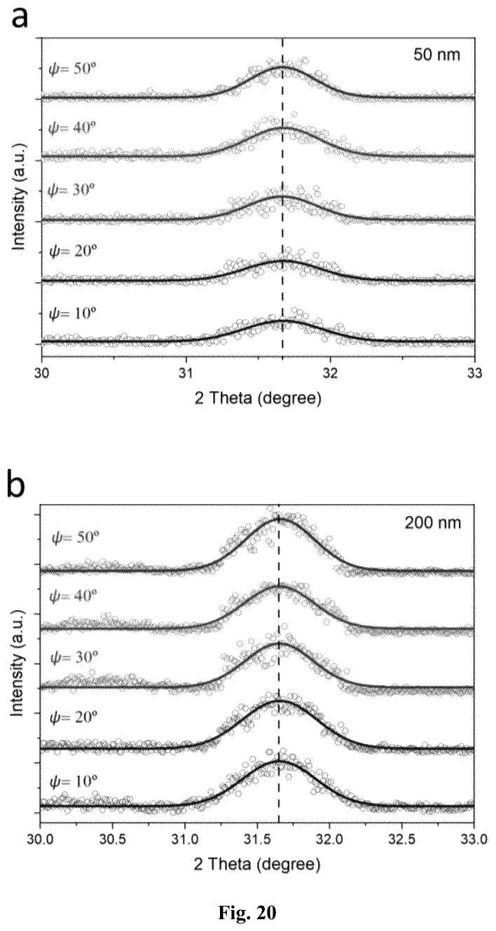

It's well known that the lattice mismatch mainly arises from unfavoured phase transition and perovskite grain propagation, inducing the residual strain and intrinsic defects in final perovskite films and eventually accelerating perovskite degradation. Here, depth-dependent grazing incident X-ray diffraction (GI-XRD) in 2θ-sin 2ψ mode was performed to identify the lattice mismatch and the evolution of residual strain across the perovskite film was analysed through varying grazing incident angles (FIGS. 3c and 3d). The nearly equivalent depth-dependent XRD patterns show that the film had the same cubic phase structure at each depth. Two typical regions (50 nm at near perovskite surface and 200 nm in bulk) was selected by varying the appropriate instrument angles (Table 3 in FIG. 36). The (012) plane at 2θ=31.6° is characteristic for strain analysis due to its high multiplicity, which is generally adopted to acquire more grain information and alleviate the orientation effect on the linear relationship of 2θ-sin 2ψ in this method. For the control sample, it is observed that a pronounced shift of (012) peak to the smaller 2θ along with the increase of instrument tilt angle ψ, which indicates an increase of crystal plane distance d₍₀₁₂₎ and thus the tensile strain bears at the near-surface region (FIG. 3c). In comparison, the position of the (012) peak almost remained unchanged for the DVS-gly based perovskite, which suggests that the soft nature of DVS-gly co-polymer scaffold could effectively diminish the uneven distribution of residual tensile strain at the near-surface region (FIG. 3d). It is observed that the same function for the DVS-gly sample in the bulk region (FIGS. 20a-b), which implies the co-polymer network may penetrate through the whole thickness of perovskite film. In-depth element analysis using X-ray photoelectron spectroscopy (XPS) was further performed to prove that the DVS-gly co-polymer was uniformly distributed across the whole perovskite film, with constant characteristic signals of S and O element within 500 s etching (FIG. 3e). These results imply that our strategy provides all-around protection at perovskite surface and GBs.

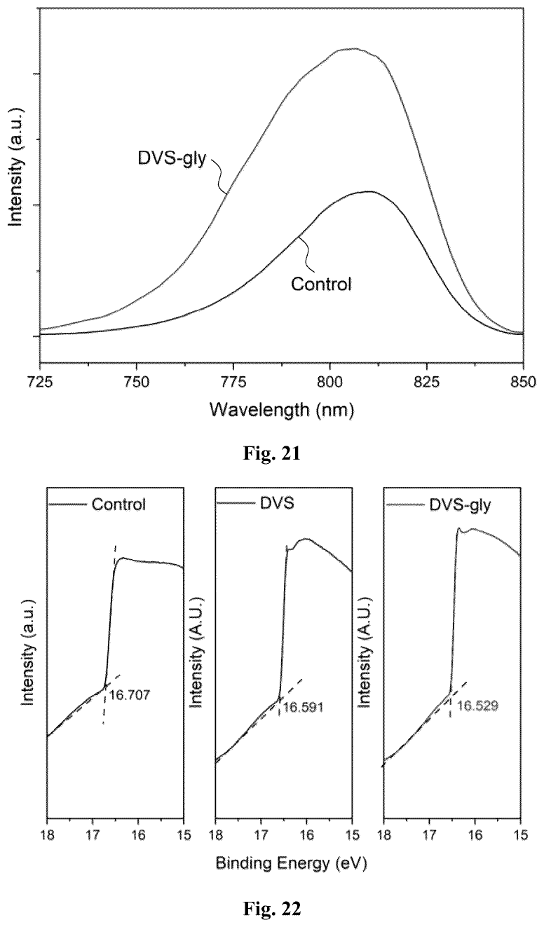

Steady-state and time-resolved photoluminescence (TRPL) spectra were conducted to explore the charge recombination behaviour in the perovskite films. The DVS-gly-based perovskite on glass substrate shows a much more pronounced and slightly blue-shifted PL peak (805 nm), compared with the control perovskite film (809 nm), which is a sign of a reduced trap density of state (tDOS) near the band tail (FIG. 21). TRPL decay spectra were fitted using the bi-exponential function, and the fitting parameters are summarized in Table 4 (FIG. 37). It should be noted that the excitation fluence in our study is very low (636.2 nm, ≤5 nJ/cm²), which only generates a much lower density of free carriers (2.4×10¹⁴ cm⁻³, much lower than the trap density) compared with that of trap states. In this condition, TRPL decay mainly responds to the trap-assisted recombination behaviour in the bulk perovskite. Compared with the control sample (782.88 ns), the DVS and DVS-gly-based samples show a much prolonged lifetime on average (4091.66 and 4682.63 ns, respectively), which indicates that this strategy significantly reduces non-radiative recombination both through the delicate crystallization manipulation and effective passivation by the co-polymer network (FIG. 3f).

### 4. Molecular Weight and Polydispersity of the Polymer Embedded in the Perovskite Layer

The optimized conditions of the cross-linking initiator DVS (DVS:DMF=7%, v:v) was used, so that the co-polymerization degree via nucleophile-mediated oxa-Michael addition reaction was precisely controlled by optimizing the molar ratio of gly versus DVS (from 4.3 to 64 mol %).

FIG. 17 and Table 3 in FIG. 36 summarize the molecular weights of the cross-linking product (DVS-gly), under different molar ratio between gly versus DVS (from 4.3 to 64 mol %), determined by gel permeation chromatography. At 4.3 mol %, a cross-linking product was yielded with very low molecular weight (Mn=12,849, Mw=20,556), inducing a high polydispersity index (PDI=Mw/Mn=1.6). The post-treatment of gly at low concentration would manipulate the cross-linking reaction into low degree, resulting in small-size but heterogeneous co-polymers. At 32 mol %, the product was yielded with much higher molecular weight (Mn=110,415, Mw=129,829), and a small PDI (1.176). This result suggests that a moderate concentration of gly post-treatment induces macroreticular and homogenous cross-linking scaffold, which enable to provide superior water-resistance in perovskite, releases residual tensile strain near surface, and suppresses deep-level defects in bulk. Further increasing the molar ratio gly to 64 mol % makes the cross-linking reaction saturated, since the limit here is originated from the reactive sites of DVS. A slightly increased molecular weight (Mn=120,808, Mw=139,021) and a similar PDI (1.151) were achieved, compared with the sample at 32 mol %. However, the post-treatment of excessive gly upon the as-cast perovskite films may induce the FAI deficit and thus disrupt the following delicate crystal growth process, and thus be detrimental to the overall crystal quality of perovskite.

Compared with the widely reported spontaneous feeding of monomer inducing uncontrollable polymerization, the asynchronous cross-linking strategy herein is a controllable reaction process.

### 4. Device Performance

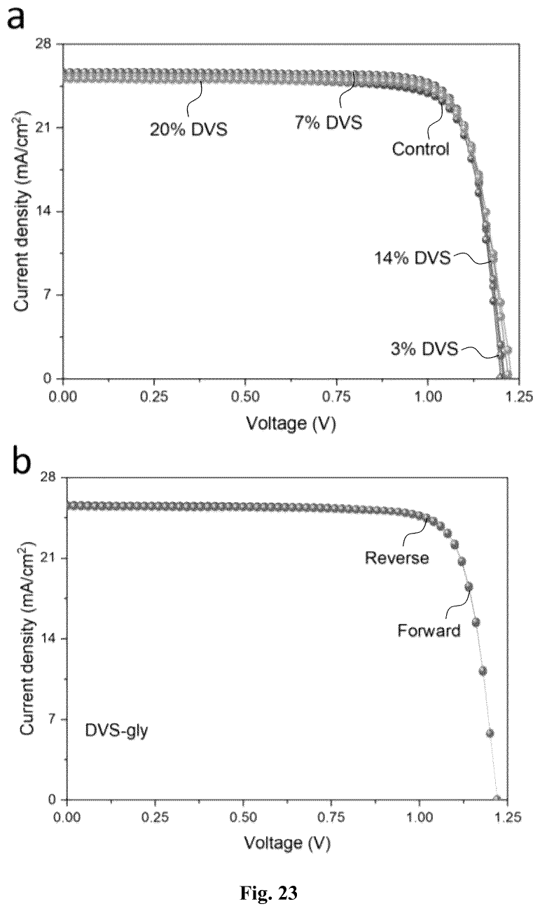

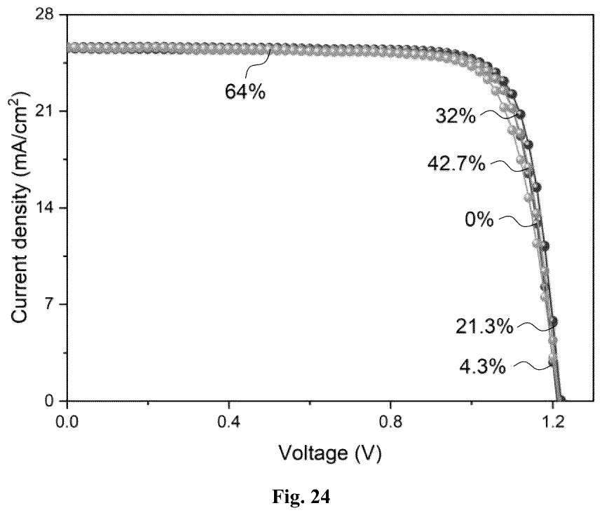

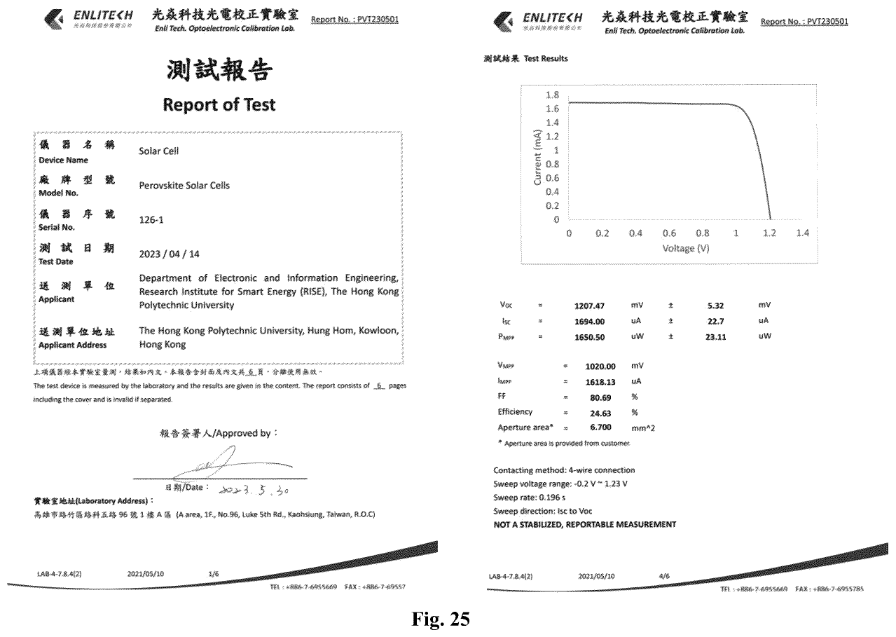

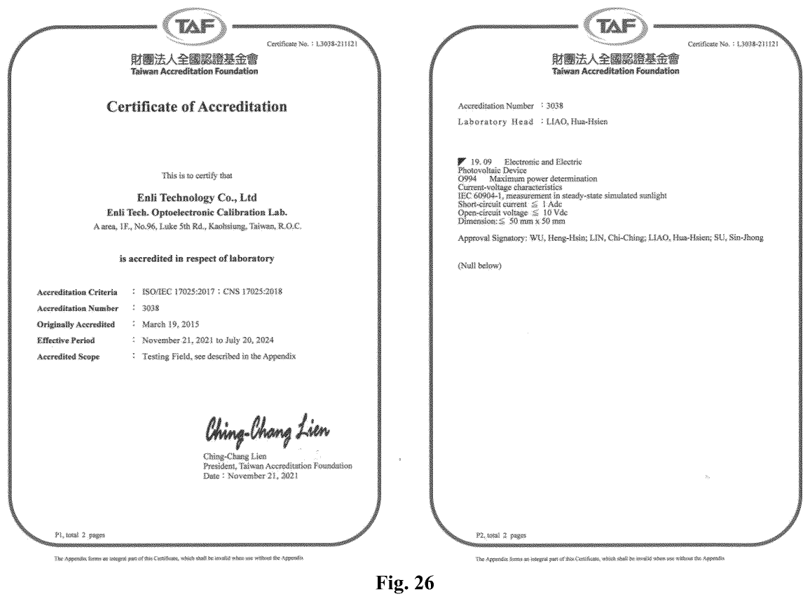

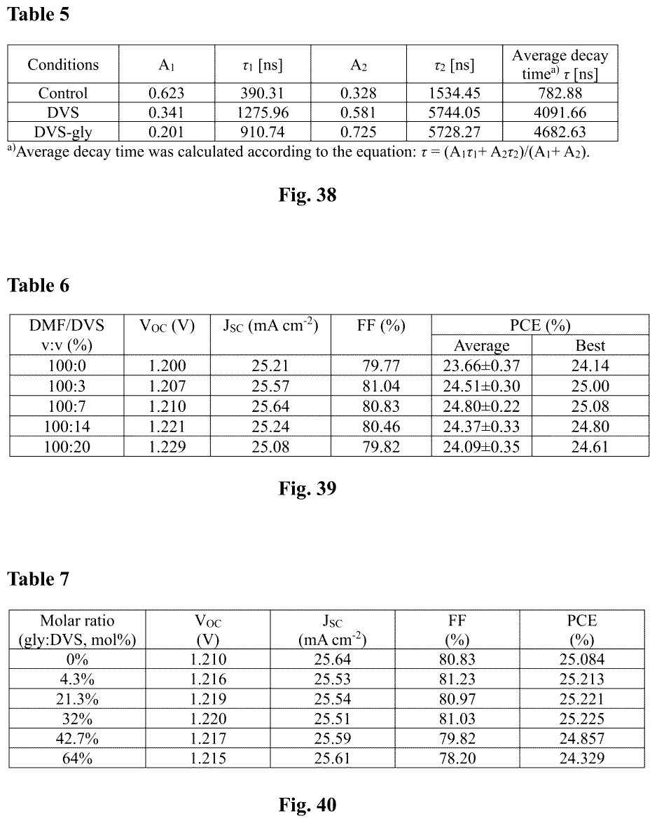

The conventional n-i-p PSCs were fabricated and assembled with the structure of FTO/TiO₂/SnO₂ QDs/perovskite/spiro-OMeTAD/Au, using the perovskite ink mixed with an appropriate amount of DVS (0 to 20%, v:v, regarding the main solvent DMF). The work functions of the corresponding perovskite films were examined by using ultraviolet photoemission spectroscopy (UPS), as shown in FIG. 22. These samples display a downward trend of work functions (−4.513, −4.629, and −4.691 eV for control, DVS, and DVS-gly-based perovskite films, which may relate to the relief of negatively charged iodine interstitial (Ii⁻) defects. FIG. 23 a shows the J-V curves of the best-performance devices under different volume ratios of DVS to DMF, and FIG. 23 b shows the representative J-V curves of the DVS-gly-based devices under forward and reverse scanning, respectively. Table 5 in FIG. 38 summarizes their photovoltaic characteristics. Along with the volume ratio DVS from 0 to 20%, V_{OC} values exhibit an increasing trend from 1.200 to 1.229 V. At the same time, JSC almost keeps constant at ˜25.2 mA cm⁻², which is well agreed with the integrated value from external quantum efficiency (EQE) spectra (FIG. 4b, less than 3% mismatch). Among them, devices from the ink with 7% DVS deliver the highest efficiency, with a maximum PCE of 25.08%. After co-polymerization through the post-treatment with gly, the efficiency of DVS-gly-based devices is significantly increased to 25.22% (certified 24.63%), as illustrated in FIG. 4a and FIGS. 25-26. FIG. 24 depicts the J-V curves at different gly concentrations (molar ratio versus DVS, from 0 to 64 mol %).

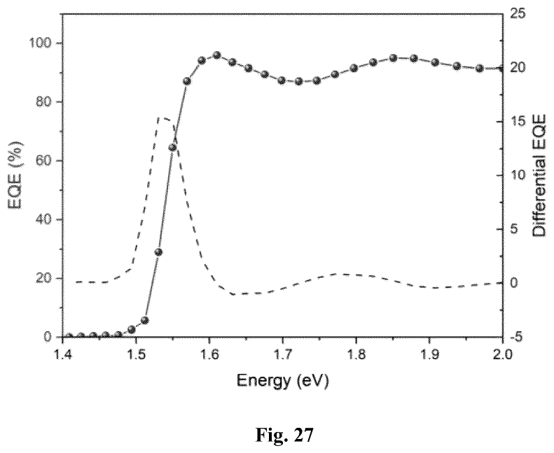

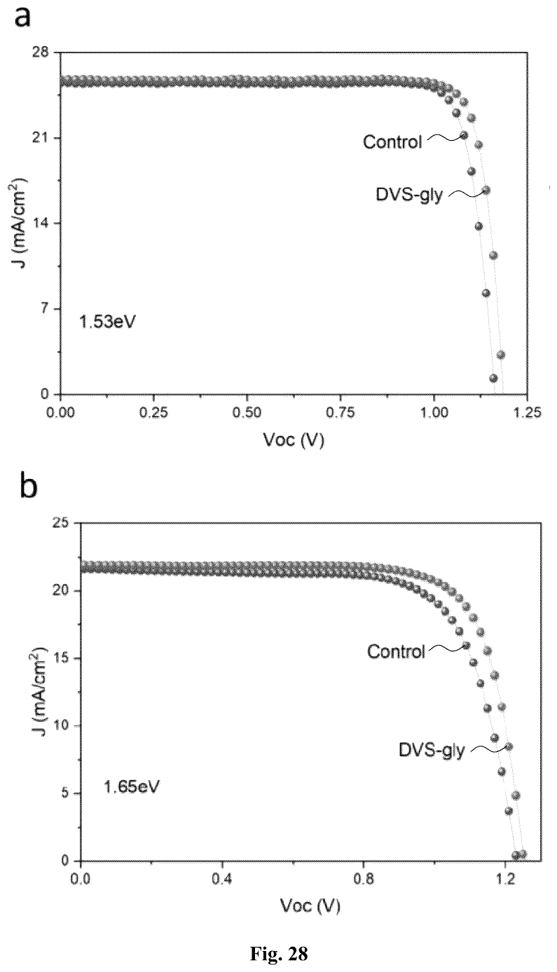

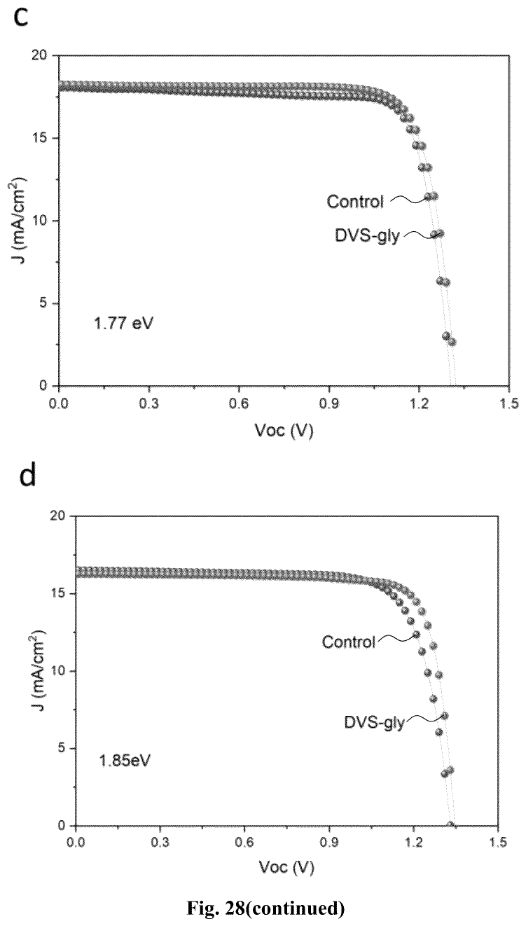

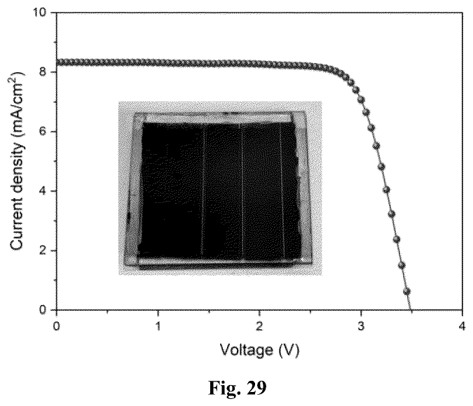

Moreover, these devices have demonstrated a maximum V_{OC} of 1.229V (FIG. 4c). Photovoltaic bandgap (EgIP) of the FA-dominated perovskite used in this work was calculated to be 1.53 eV from the first differential of EQE spectra (FIG. 27). As far as we known, 1.229V V_{OC} is the highest reported value in this bandgap of perovskite, and the corresponding V_{OC} deficit (0.301 V) is the lowest among all perovskite systems (Table 6 in FIG. 39). It is noteworthy that the V_{OC} of our devices reached 97.5% of the theoretical V_{OC} limit, as demonstrated in FIG. 4d. It is also validated this strategy on p-i-n structured devices, based on different perovskite compositions, delivering a maximum PCE of 25.98% with enhanced V_{OC} (FIGS. 28a-d and Table 7 in FIG. 40). When upscaling the device area, we achieved the maximum PCE of 21.75% for the minimodule (3-subcells, 3.6*3.6 cm² substrate, FIG. 29).

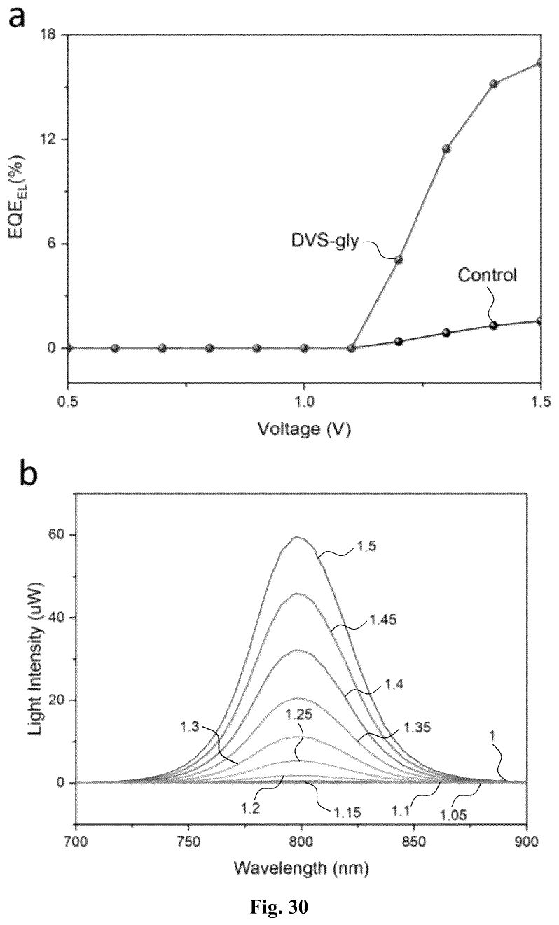

By quantifying the dominated recombination mechanisms, we uncover the increase of V_{OC} in DVS-gly-based devices using the electroluminescence method. We measured the external quantum efficiency of electroluminescence (EQE_{EL}) when a PSC operating as a light-emitting diode (LED) in forward voltage bias (FIG. 4e and FIGS. 30a-b). The non-radiative recombination loss (ΔV_{OC}, nr) can be derived from the EQE_{EL} at the injection current density equal to JSC. Compared with the control device (EQE_{EL}=1.28%, ΔV_{OC}, nr=113 mV), The DVS-gly device exhibits a much-enhanced EQE_{EL} of 13.11% at the injection current density equal to JSC, corresponding to a ΔV_{OC}, nr of 52.5 mV, coincident with the V_{OC} deficit from J-V test. This result indicates the hybrid asynchronous cross-linking significantly suppresses the non-radiative recombination at perovskite surface and GBs, which dominates the V_{OC} enhancement for the DVS-gly-based devices.

Thermal admittance spectroscopy (TAS) was further performed to quantitatively estimate the energetic distribution of trap density of states (tDOS) under an AC voltage with the frequency decreased from 10⁶ Hz to 100 Hz. Compared with the control device (Nt=8.33×10¹⁶ cm⁻³), the DVS-gly-based devices display much lower trap density (Nt=5.09×10¹⁶ cm⁻³) (FIG. 4f). It's well known that deep defects (>0.35 eV here) at perovskite surface and GBs are mainly regarded as the non-radiative recombination center, which is significantly detrimental to the V_{OC} of PSCs. DVS-gly strategy not only manipulates the delicate crystallization process through the favoured intermediate-dominated transition, delivering high-quality perovskite crystal but also relieves these intrinsic defects via the controllable co-polymerization at perovskite surface and GBs efficiently. The strategy in the application synergistically eliminates the intrinsic deep defects to a great extent and pushes the V_{OC} value close to the radiative limit.

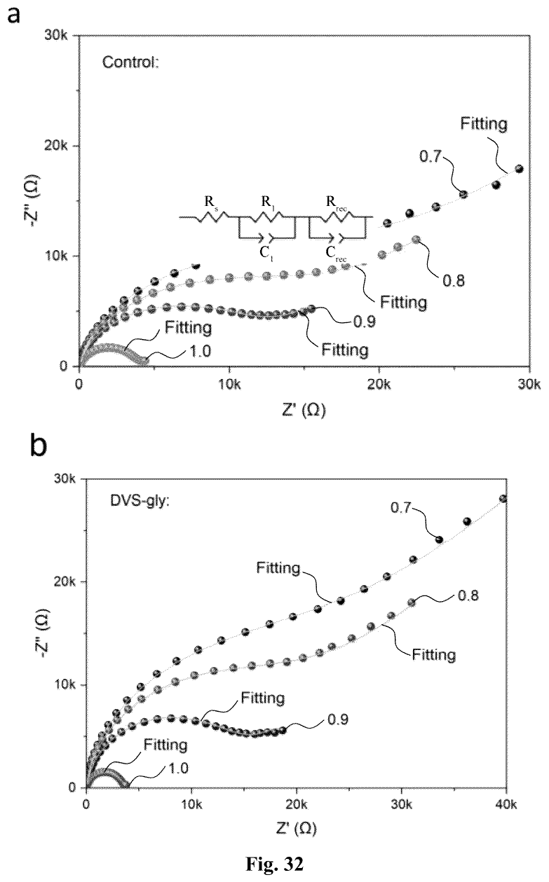

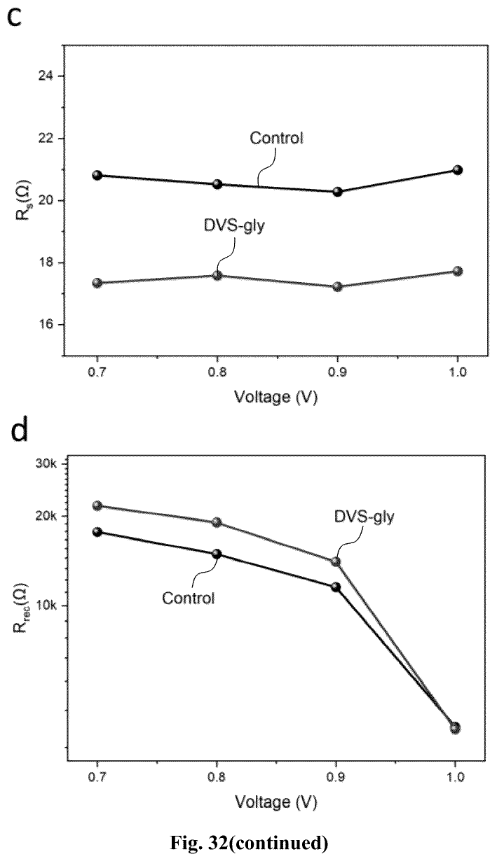

To further study the charge transport/recombination behaviour in PSCs, we performed electrochemical impedance spectroscopy (EIS). FIGS. 32a and 32b show Nyquist plots for the control and DVS-gly-based devices under AC bias frequency from 106 Hz to 100 Hz, respectively. The equivalent circuit for simulating charge transfer and recombination is shown in the set of this figure, in which R_{S} is the series resistance of the devices, and R_{rec} is the recombination resistance in the bulk perovskite, inversely related to the rate at which photogenerated carrier recombination.

The DVS-gly devices show lower RS than that of the control devices, which is highly related to the enhanced FF measured by J-V curves (FIG. 32c). More importantly, the higher R_{rec} for the DVS-gly devices is mainly responsible for the reduced recombination rate of photogenerated carriers in the bulk perovskite (FIG. 32d), which is in accordance with the enhanced V_{OC} as mentioned before.

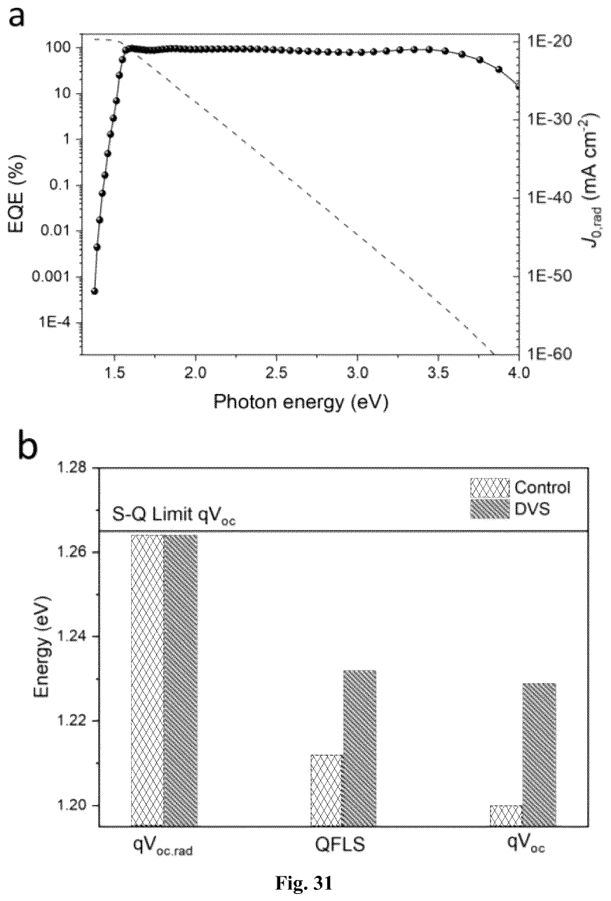

To further elucidate the V_{OC} deficit, the quasi-Fermi-level splitting (QFLS) was derived from the analysis of photoluminescence (PL), as shown in FIG. 31. Firstly, the radiative limit of open-circuit voltage (V_{oc,rad}) is determined by the following formula:

$${V}_{oc , rad} = \frac{{k}_{B} T}{q} ln ( 1 + \frac{\int EQ E ( E ) {ϕ}_{AM 1.5 G} ( E ) dE}{\int EQE ( E ) {ϕ}_{bb} ( E ) dE} ) \qquad ( 2 )$$

$${ϕ}_{bb} ( E ) = \frac{2 π {E}^{2}}{{h}^{3} {c}^{2}} \cdot \frac{1}{\frac{E}{{e}^{{k}_{B} T} - 1}} \approx \frac{2 π {E}^{2}}{{h}^{3} {c}^{2}} \cdot {e}^{\frac{E}{{{k}_{B} T}^{}}} \qquad ( 3 )$$

in which h is Planck's constant (6.626×10⁻³⁴ J·s), c is the light speed (3.0×10⁸ m/s). E is the photon energy, typically measured in electron volts (eV). k_{B} is the Boltzmann constant, with a value of 1.380649×10⁻²³ J/K. T is the absolute temperature, typically taken as 300 K at room temperature. φ_{Am1,5G}(E) denotes the spectrum of standard AM1.5G solar irradiation, EQE(E) is the external quantum efficiency. φ_{bb}(E) represents the spectrum of black-body radiation at temperature T=300 K. After calculation, we get the dark radiative recombination current (J_{0,rad}) of 1.42×10⁻²⁰ mA/cm², and the V_{OC,rad} of 1.264 V, as shown in FIG. 31a.

Based on the measured photoluminescence quantum yield (PLQY, 13.24% for the control sample, 28.53% for the DVS-gly sample), the quasi-Fermi level splitting (QFLS) is determined by the following equation:

$$QFLS = {qV}_{OC , rad} + {k}_{B} T ln ( PLQY ) . \qquad ( 4 )$$

Combining QFLS with the extracted q V_{OC, rad}, and the measured qV_{OC} of the devices, we elucidated the origins of low V_{OC} deficit under our strategy (see Table 10 in FIG. 43). There is a substantially decreased energy loss, according to the difference between qV_{OC},rad and QFLS, Δ(V_{OC,rad}−QFLS), from 52 to 32 meV. From QFLS analysis, it is concluded that the origin of record-low V_{OC} deficit is primarily attributed to efficient elimination of non-radiative recombination at perovskite surface and grain boundary via the resulting DVS-gly network.

### 5. Perovskite Layer Water Resistance and Device Stability

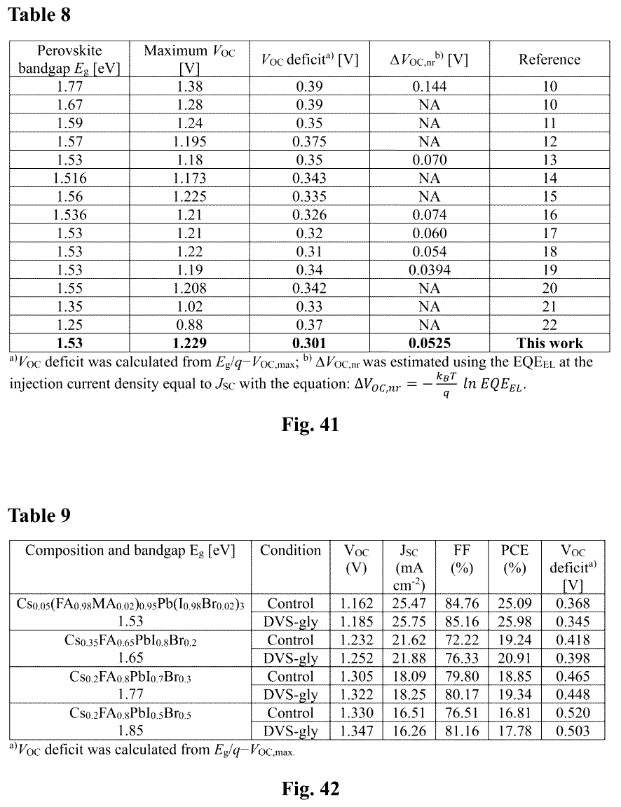

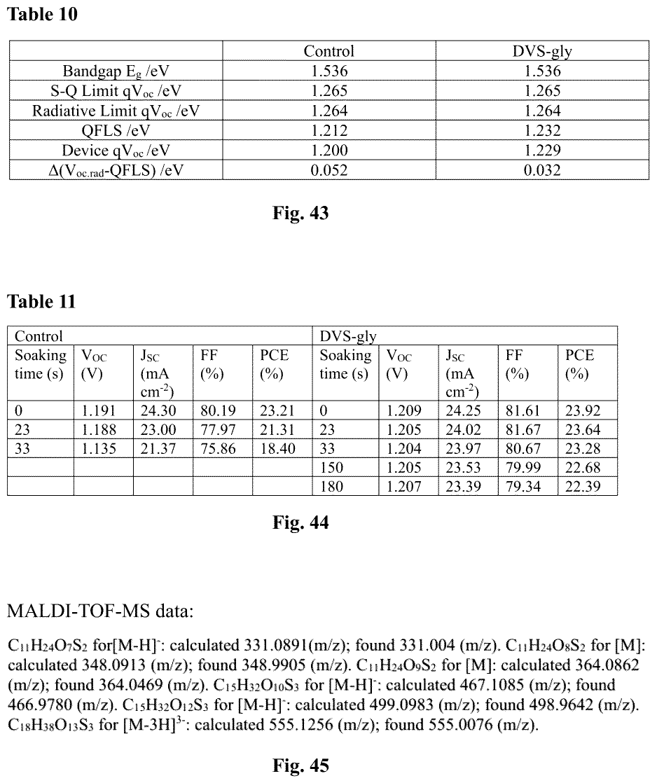

In addition to the device performance, the long-term stability under various aging conditions, especially the long-term operational stability, is of great significance for the future commercialization of PSC technology. The DVS-gly co-polymerization strategy provided superior moisture resistance to the perovskite films through inner encapsulation (FIGS. 5a and 5b). Compared to the control perovskite film which turns yellow immediately, while, the DVS-gly protected perovskite film kept black even after 180 s in water. The unencapsulated DVS-gly-based perovskite devices also exhibit much-improved stability directly under water soaking (Table 8 in FIG. 41). Table 11 in FIG. 44 shows photovoltaic parameters of unencapsulated devices immersed into water as a function of time. The unencapsulated DVS-gly-based perovskite devices also exhibit much-improved stability directly under water soaking, retaining over 93% of its initial efficiency after 180 s water soaking, compared with a short lifetime of 79% after 33 s for the control devices.

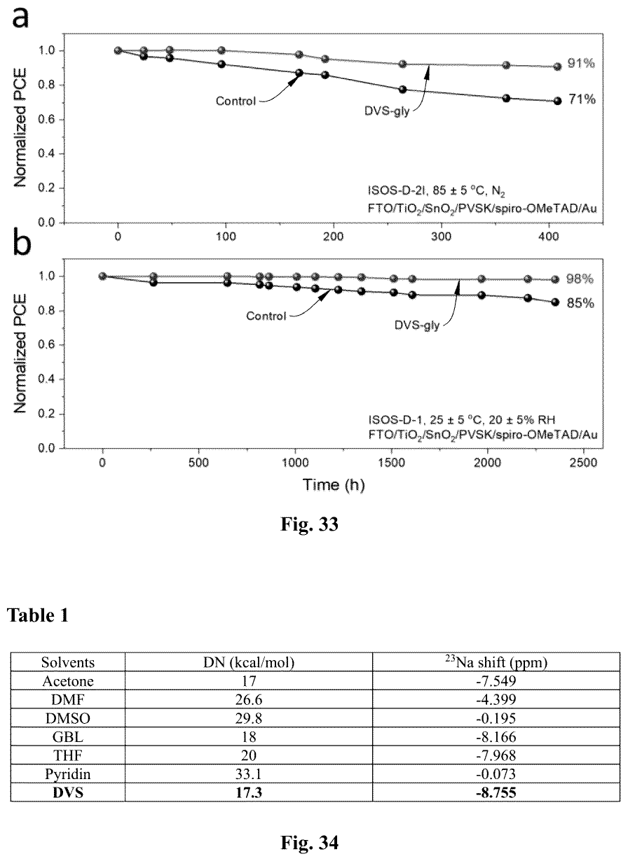

For the long-term stability, the PCE evolution for the control and DVS-gly based devices were monitored under MPP tracking and continuous 1-sun illumination at elevated temperature (ISOS-L-3: 65±5° C., 50±5% RH, PTAA based n-i-p devices) and room temperature (ISOS-L-1: 30±5° C., 60±5% RH, spiro-OMeTAD based n-i-p devices), respectively. DVS-gly based devices maintained over 98% of their initial PCE after 1350 h operation at 65° C., and 90% after 1800 h operation at 30° C., respectively, which are significantly superior to those of the control devices (FIGS. 5c and 5d). Besides, the thermal stability of PSCs was evaluated based on different HTLs, as shown in FIG. 5e and FIG. 33a, respectively) in dark (ISOS-D-2I, 85±5° C., N₂). PTAA-based devices exhibit much prolonged thermal stability than spiro-OMeTAD, mainly due to the absence of metal ionic dopants. DVS-gly devices based on PTAA maintained over 95% of their initial PCE after 1560 h, which is superior to the control devices (only maintaining 64%), mainly attributed to the reduced tDOS at perovskite surface and GBs. DVS-gly devices also exhibit enhanced shelf stability under ambient atmosphere (25±5° C., 20±5% RH, maintaining 98% of their initial PCE over 2300 h, as shown in FIG. 33b). It's well known that shallow defects (with low migration activation energy) at perovskite surface and grain boundaries initialize the permeation of moisture and oxygen into the perovskite films to accelerate the degradation of PSCs. The effective relief of shallow defects and superior moisture resistance through this strategy is responsible for enhanced stability under different aging conditions.

The disclosed experimental data was designed to establish the feasibility and reproducibility of the claimed process under representative conditions. The chosen materials and process parameters reflect the desired outcomes and are aligned with standard practices in the field. The focus of the current disclosure was to demonstrate the viability of the process under the specific conditions described. While the experimental data provided focuses on specific conditions, the process is not intended to be limited to these embodiments. The methodology described herein is adaptable to a range of conditions, and variations in the components could be explored to optimize the process for specific applications. The selection of the described parameters was based on their practical relevance and alignment with the objectives of this invention.

What is claimed is:

1. A polymer-embedded perovskite layer comprising a crosslinked polymer matrix and a perovskite compound, wherein the crosslinked polymer matrix comprises a first repeating unit represented by —CH₂CH₂SO₂CH₂CH₂— and a second repeating unit represented by a polyol and the perovskite compound is represented by Formula 1: 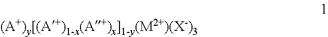
wherein x is a numerical value ranging from 0-0.99, and y is a numerical value ranging from 0.01-0.99;
M²⁺ is Pb²⁺, Sn²⁺, or Ge²⁺;
A⁺ is Cs⁺ or Rb⁺;
A′⁺ is H(C═NH₂)NH₂⁺;
A″⁺ is CH₃NH₃⁺, CH₃CH₂NH₃⁺, or Me(C═NH₂)NH₂⁺; and
X⁻ is one or more of Cl⁻, Br⁻, or I⁻.

2. The polymer-embedded perovskite layer of claim 1, wherein the polyol comprises a diolyl, a triolyl, a tetraolyl, or a mixture thereof.

3. The polymer-embedded perovskite layer of claim 1, wherein the polyol comprises ethylene glycolyl, propylene glycolyl, glyceryl, trimethylolpropanyl, trimethylolethanyl, erythritolyl, pentaerythritolyl, bis-trimethylolpropanyl, diethylene glycolyl, dipropylene glycolyl, ethoxylated pentaerythritolyl, sorbitolyl, or mixtures thereof.

4. The polymer-embedded perovskite layer of claim 1, wherein M²⁺ is Pb²⁺; A⁺ is Cs⁺ and A″⁺ is CH₃NH₃⁺.

5. The polymer-embedded perovskite layer of claim 1, wherein the perovskite comprises (Cs⁺)_{y}[(H(C═NH₂)NH₂⁺)₁₋ₓ(CH₃NH₃⁺)ₓ]_{1-y}(Pb²⁺)[I⁻)_{1-z}(Br⁻)_{z})]₃, wherein each of x, y and z is independently a numerical value ranging from 0.01-0.99.

6. The polymer-embedded perovskite layer of claim 1, wherein the polyol is glyceryl.

7. The polymer-embedded perovskite layer of claim 1, wherein each of x and y is independently a numerical value ranging from 0.01-0.1.

8. The polymer-embedded perovskite layer of claim 1, wherein the crosslinked polymer matrix has a weight average molecular weight in the range of 20,000 to 140,000.

9. The polymer-embedded perovskite layer of claim 1, wherein the molar ratio of the second repeating unit to the first repeating unit is 4-64:100.

10. A method for producing the polymer-embedded perovskite layer of claim 1, wherein the method comprises:
providing a perovskite precursor solution comprising one or more metal salts each independently represented by the formula MX₂, three or more salts each independently represented by the formulas AZ, A′Z or A″Z, divinyl sulfone, and a solvent, wherein M is Pb²⁺, Sn²⁺, or Ge²⁺, A is Cs⁺ or Rb⁺, A′ is H(C═NH₂)NH₂⁺, A″ is CH₃NH₃⁺, CH₃CH₂NH₃⁺, or Me(C═NH₂)NH₂⁺, X for each instance is independently Cl⁻, Br⁻, or I⁻, and Z for each instance is independently Cl⁻, Br⁻, or I⁻;
contacting the perovskite precursor solution with a polyhydric alcohol to form a crosslinking precursor solution; and
annealing the crosslinking precursor solution to form the perovskite layer.

11. The method of claim 10, wherein the perovskite precursor solution comprises (Cs⁺)(I⁻), (H(C═NH₂)NH₂⁺)(I⁻), (CH₃NH₃⁺)(Br⁻), (CH₃NH₃⁺)(Cl⁻), (Pb²⁺)(Br⁻)₂, and (Pb²⁺)(I⁻)₂.

12. The method of claim 10, wherein the solvent comprises dimethyl formamide, dimethyl sulfoxide, N-methyl-2-pyrrolidone (NMP), N,N′-dimethylpropyleneurea (DMPU), or mixtures thereof.

13. The method of claim 10, wherein the volume ratio of divinyl sulfone to the solvent is 1-20:100.

14. The method of claim 10, wherein the one or more metal salts have a concentration from 0.2 to 1.5 M in the perovskite precursor solution.

15. The method of claim 10, wherein the molar ratio of polyhydric alcohol to divinyl sulfone is 4-64:100.

16. The method of claim 10, wherein the crosslinking precursor solution is annealed at a temperature of 100-120° C.

17. A photoelectric device comprising the perovskite layer of claim 1.

18. The photoelectric device of claim 17, wherein the photoelectric device is a perovskite solar cell (PSC), a perovskite light-emitting diode, a perovskite laser, or a perovskite photodetector.

19. The photoelectric device of claim 18, wherein the open circuit voltage of the perovskite solar cell is 1.162-1.347V.

20. The photoelectric device of claim 18, wherein the photoelectric conversion efficiency of the perovskite solar cell is 17.78-25.98%.
